(19) United States
(12) Patent Application Publication
(10) Pub. No.: US 2025/0309061 A1
(43) Pub. Date: Oct. 2, 2025

(54) LEAD FRAME DESIGNS FOR ENHANCED IC PACKAGE AND DIE ROBUSTNESS

(71) Applicant: Allegro MicroSystems, LLC, Manchester, NH (US)

(72) Inventors: Weidong Wang, Westford, MA (US); Huang Huang, Arlington, MA (US); Natasha Healey, Manchester, NH (US)

(73) Assignee: Allegro MicroSystems, LLC, Manchester, NH (US)

(21) Appl. No.: 18/624,271

(22) Filed: Apr. 2, 2024

(51) Int. Cl. H01L 23/495; G01R 33/07; G01R 33/09

(52) U.S. Cl. CPC H01L 23/49503; G01R 33/07; G01R 33/09; H01L 23/49517

(57) ABSTRACT

A magnetic field sensor comprises a die, first and second magnetic field sensing elements supported by the die, at respective spaced apart positions, and a lead frame supporting the die. The lead frame comprises a die attach segment having first and second openings formed therein, where there is no lead frame covering either magnetic field sensing element. The die attach segment includes a horizontal support portion disposed between the first and second openings, having a size configured to provide die support along a predetermined portion of at least one predetermined horizontal axis of the die. In other aspects, the lead frame comprises multiple die attach segments separated by slots, where at least one of the multiple die attach segments supports the die along its horizontal axis. At least one of the slots mitigates a current loop arising from operation of at least one of the magnetic field sensing elements.

### FIELD

Embodiments of the disclosure generally relate to devices, systems, and methods for providing packaging for electronic circuits. More particularly, the disclosure describes embodiments relating to devices, systems, and methods to provide lead frames for integrated circuits that help to reduce die cracking during handling and test.

### BACKGROUND

Techniques for semiconductor packaging are well known in the art. In general, a semiconductor die is cut from a wafer, processed, and attached to a die attach pad of a lead frame. As is known, a lead frame is a structure (advantageously made from an electrically conductive and/or thermally conductive material, such as a metal or metal alloy) that is provided inside a semiconductor package. The lead frame helps to carry signals from the semiconductor die to the outside world, and in some instances the lead frame may form an integral part of a heat sink for the semiconductor die. Lead frames also help to hold the semiconductor die in place during later manufacturing steps, such as encapsulation. Materials usable for lead frames include, but are not limited to, combinations of electrically conductive materials, such as copper or copper alloys. A number of semiconductor packaging technologies use lead frames and are used in various packaging technologies, including but not limited to quad flat no-leads (QFNs), quad flat packages (QFPs), small outline integrated circuits (SOICs), dual in-line packages (DIPs), and plastic quad flat packs (PQFPs)

Some semiconductor dies include magnetic field sensing elements formed therein or attached thereto, such as Hall sensors. The semiconductor die in which the magnetic field sensing element is formed or attached may be attached to the lead frame by various techniques, such as with an adhesive tape or epoxy, and may be electrically coupled to the lead frame by various techniques, such as with solder bumps or wire bonding. Also, the lead frame may take various forms and the semiconductor die may be attached to the lead frame in an orientation with the active semiconductor surface (i.e., the surface in which the magnetic field sensing element is formed) being adjacent to the lead frame in a so called “flip-chip” arrangement, with the active semiconductor surface opposite the lead frame surface in a so called “die up” arrangement, or with the semiconductor die positioned below the lead frame in a so called “Lead on Chip” arrangement.

After the semiconductor die is attached to the lead frame, to form a subassembly, this subassembly may then be encapsulated (e.g., overmolded) with a protective and electrically insulative material, such as a plastic potting material) to form an integrated circuit (IC) package. Various molding techniques have been used, including injection molding and transfer molding. After packaging, the IC may then be placed on a circuit board with other components, including passive components such as capacitors, resistors, and inductors, which can be used for filtering and other functionality.

For the case of a magnetic field sensor integrated circuit containing a magnetic field sensing element, such magnetic field sensors can include a magnetic field sensing element, or transducer, such as a Hall Effect element or a magnetoresistive element, are used in a variety of applications to detect aspects of movement of a ferromagnetic article, or target, such as proximity, speed, and direction. Illustrative applications include, but are not limited to, a magnetic switch or “proximity detector” that senses the proximity of a ferromagnetic article, a proximity detector that senses passing ferromagnetic articles (for example, magnetic domains of a ring magnet or gear teeth), a magnetic field sensor that senses a magnetic field density of a magnetic field, and a current sensor that senses a magnetic field generated by a current flowing in a current conductor. Magnetic field sensors are widely used in automobile control systems, for example, to detect ignition timing from a position of an engine crankshaft and/or camshaft, and to detect a position and/or rotation of an automobile wheel for anti-lock braking systems.

### SUMMARY

The following presents a simplified summary to provide a basic understanding of one or more aspects of the embodiments described herein. This summary is not an extensive overview of all of the possible embodiments and is neither intended to identify key or critical elements of the embodiments, nor to delineate the scope thereof. Rather, the primary purpose of the summary is to present some concepts of the embodiments described herein in a simplified form as a prelude to the more detailed description that is presented later.

In one aspect, a magnetic field sensor is provided, comprising a die, a first magnetic field sensing element supported by the die, a second magnetic field sensing element supported by the die and a lead frame configured for supporting the die. The first magnetic field sensing element is disposed at a first position on the die. The second magnetic field sensing element is disposed at a second position on the die, wherein the second position is spaced apart from the first position. The lead frame has opposed first and second surfaces and comprises: at least one die attach segment to which the die is attached, a first opening formed in the die attach segment, and a second opening formed in the die attach segment.

The at least one die attach segment is configured to support the die. The first opening is configured to create a first discontinuity between the first and second surfaces of the lead frame, wherein a size and a location of the first discontinuity is selected so that that there is no lead frame covering the first magnetic field sensing element. The second opening is formed in the die attach segment and is configured to create a second discontinuity between the first and second surfaces of the lead frame, wherein a size and a location of the second discontinuity is selected so there is no lead frame covering the second magnetic field sensing element, wherein the second opening is spaced apart from the first opening. The die attach segment is configured to include at least one horizontal support portion disposed between the first opening and the second opening, wherein the horizontal support portion has a size that is configured to provide support to the die along a predetermined portion of at least one predetermined horizontal axis of the die.

In some embodiments, the predetermined portion of the at least one predetermined horizontal axis of the die comprises a majority of the at least one predetermined horizontal axis of the die. In some embodiments, the predetermined portion of the at least one predetermined horizontal axis of the die, comprises an entirety of the at least one predetermined horizontal axis of the die. In some embodiments, the at least one predetermined horizontal axis runs through a center of the die. In some embodiments, the first opening has a first opening length and a first opening width, and the size of the horizontal support portion is based on at least one of the first opening width and the first opening length. In some embodiments, the at least one predetermined horizontal axis comprises a horizontal axis aligned with a center of the die. In some embodiments, the first opening is symmetrical about a vertical axis running through a center of the die. In some embodiments, the magnetic field sensor further comprises a plurality of leads configured for operable connection to the die, wherein the lead frame is electrically isolated from at least some of the plurality of leads.

In another aspect, a magnetic field sensor is provided, comprising a die, a magnetic field sensing element supported by the die, and a lead frame and a lead frame configured for supporting the die. The magnetic field sensor is disposed at a first position on the die. The lead frame has opposing first and second surfaces and comprises a first die attach segment to which the die is attached, a second die attach segment to which the die is attached, and a third die attach segment to which the die is attached. The second die attach segment comprises a first portion, a second portion, and a third portion, wherein: the first portion is spaced apart from the first die attach segment via a first opening; the second portion is aligned along a horizontal axis of the die and is configured to support the die along a predetermined portion of the horizontal axis of the die; and the third portion is spaced apart from the first die attach segment via a first slot. The third die attach segment is spaced apart from the third portion of the second die attach segment via a second opening and spaced apart from the second portion of the second die attach segment via a second slot. At least one of the first opening and the second opening is configured to create a respective discontinuity between the first and second surfaces of the lead frame, wherein a size and a location of the respective discontinuity is selected so that there is no lead frame covering the first magnetic field sensing element. In addition, at least one of the first slot and the second slot is configured to mitigate a current loop arising from operation of the first magnetic field sensing element.

In certain embodiments, the horizontal axis of the die runs through a center point of the die. In certain embodiments, the first die attach segment and the first portion of the second die attach segment are disposed on opposing sides of a vertical axis that runs through a center of the die. In certain embodiments, the third portion of the second die attach segment and the third die attach segment are disposed on opposing sides of a vertical axis that runs through a center of the die. In certain embodiments, at least one of the first slot and second slot is at an angle with respect to the horizontal axis of the die. In certain embodiments, at least one of the first slot and second slot is at an angle with respect to the horizontal axis of the die.

In certain embodiments, the magnetic field sensor further comprises a third slot disposed within the second portion and aligned along a vertical axis of the die. In certain embodiments, the third slot is aligned along a vertical axis that runs through a center point of the die. In certain embodiments, the third slot is configured to be at an angle to a vertical axis that runs through a center point of the die.

In certain embodiments, the magnetic field sensor further comprises a plurality of leads configured for operable connection to the die. In certain embodiments, the first die attach segment, second die attach segment, and third die attach segment are each configured to be in operable communication with a respective lead from the plurality of leads. In certain embodiments, the first die attach segment, second die attach segment, and third die attach segment are configured to be electrically isolated from each other.

It should be appreciated that individual elements of different embodiments described herein may be combined to form other embodiments not specifically set forth above. Various elements, which are described in the context of a single embodiment, may also be provided separately or in any suitable sub-combination. It should also be appreciated that other embodiments not specifically described herein are also within the scope of the claims included herein.

Details relating to these and other embodiments are described more fully herein.

### BRIEF DESCRIPTION OF THE DRAWINGS

The advantages and aspects of the described embodiments, as well as the embodiments themselves, will be more fully understood in conjunction with the following detailed description and accompanying drawings, in which:

FIG. 1A illustrates a top view of a portion of a first exemplary prior art lead frame;

FIG. 1B illustrates a top view of the exemplary first prior art lead frame of FIG. 1A operably coupled to an exemplary first prior art semiconductor die and as assembled into a first prior art package;

FIG. 1C is a cross-section view of the first prior art package of FIG. 1B, taken along the B-B line of FIG. 1B;

FIG. 1D is a cross section view of the first prior art package of FIG. 1B, taken along the B1-B1 line of FIG. 1B;

FIG. 2A is a top view of a second assembly that includes a second exemplary prior art lead frame operably coupled to an exemplary second prior art semiconductor die that includes a magnetic sensing element;

FIG. 2B is a top view of the second assembly of FIG. 2A, showing the assembly after overmolding into a second prior art package;

FIG. 3 is a top view of third prior art assembly showing the first exemplary prior art lead frame of FIG. 1A coupled to a first type of semiconductor die;

FIG. 4 is a top view of a fourth prior art assembly showing the first exemplary prior art lead frame of FIG. 1A coupled to a second type of semiconductor die;

FIG. 5 is a top view of a fifth prior art assembly showing the first exemplary prior art lead frame of FIG. 1A coupled to a third type of semiconductor die;

FIG. 6A is a top view of a portion of a first modified lead frame, in accordance with one embodiment;

FIG. 6B is a top view of a portion of a first alternate embodiment of the first modified lead frame, in accordance with one embodiment;

FIG. 6C is a top view of a portion of a second alternate embodiment of the first modified lead frame, in accordance with one embodiment;

FIG. 6D is a top view of a portion of a third alternate embodiment of the first modified lead frame, in accordance with one embodiment;

FIG. 7A is a cross-section view of the first modified lead frame of FIG. 6A, as coupled to a die and encapsulated, taken along the C-C line of FIG. 6A, in accordance with one embodiment;

FIG. 7B is a cross-section view of the first alternate embodiment of the first modified lead frame of FIG. 6B, as coupled to a die and encapsulated, taken along the C-C line of FIG. 6B, in accordance with one embodiment;

FIG. 7C is a cross-section view of the second alternate embodiment of the first modified lead frame of FIG. 6C, as coupled to a die and encapsulated, taken along the C1-C1 line of FIG. 6C, in accordance with one embodiment;

FIG. 7D is a cross-section view of the second alternate embodiment of the first modified lead frame of FIG. 6D, as coupled to a die and encapsulated, taken along the G-G line of FIG. 6D, in accordance with one embodiment;

FIG. 8 is a top view of the first modified lead frame of FIG. 6A, attached to the first type of semiconductor die, in accordance with one embodiment;

FIG. 9 is a top view of the first modified lead frame of FIG. 6A, attached to the second type of semiconductor die, in accordance with one embodiment;

FIG. 10 is a top view of the first modified lead frame of FIG. 6A, attached to the third type of semiconductor die, in accordance with one embodiment;

FIG. 11 is a top view of a second modified lead frame, in accordance with one embodiment;

FIG. 12 is a cross-section view of the second modified lead frame of FIG. 11, as coupled to a die and encapsulated, taken along the F-F line of FIG. 11, in accordance with one embodiment;

FIG. 13 is a top view of the second modified lead frame of FIG. 11, attached to the first type of semiconductor die, in accordance with one embodiment;

FIG. 14 is a top view of the second modified lead frame of FIG. 11, attached to the second type of semiconductor die, in accordance with one embodiment;

FIG. 15 is a top view of the second modified lead frame of FIG. 11, attached to the third type of semiconductor die, in accordance with one embodiment;

FIG. 16 is top view of the exemplary prior art lead frame of FIG. 1A as encapsulated with the first prior art type of semiconductor die, used during the simulation testing that generated the data shown in the graphs of FIGS. 20-23, in accordance with one embodiment;

FIG. 17 is a top view of the first modified lead frame of FIG. 6A as encapsulated with the first prior art type of semiconductor die, used during the simulation testing that generated the data shown in the graphs of FIGS. 20-23, in accordance with one embodiment;

FIG. 18 is a top view of the second modified lead frame of FIG. 11, as encapsulated with the first prior art type of semiconductor die, used during the simulation testing that generated the data shown in the graphs of FIGS. 20-23, in accordance with one embodiment;

FIG. 19A is a graphic depicting the locations of applied tapper force for the simulation testing associated with the graphs of FIGS. 20-23, in accordance with one embodiment;

FIG. 19B is a graphic depicting the locations of applied holder force for the simulation testing associated with the graphs of FIGS. 20-23, in accordance with one embodiment;

FIG. 20 is a chart of simulation testing results for die stress under holder force, comparing the prior art lead frame of FIG. 1 to the first modified lead frame of FIG. 6A and the second modified lead frame of FIG. 11, encapsulated into the structures shown in FIGS. 16-18, respectively, in accordance with one embodiment;

FIG. 21A is a graph of simulation testing results, showing die max principal stress as a function of applied tapper force, for the prior art lead frame of FIG. 1, the first modified lead frame of FIG. 6A and the second modified lead frame of FIG. 11, encapsulated into the structures shown in FIGS. 16-18, respectively, in accordance with one embodiment;

FIG. 21B is a graph of simulation testing results, showing die max principal stress as a function of applied holder force, for the prior art lead frame of FIG. 1, the first modified lead frame of FIG. 6A, and the second modified lead frame of FIG. 11, encapsulated into the structures shown in FIGS. 16-18, respectively, in accordance with one embodiment;

FIG. 22 is a graph of a graph of simulation testing results, showing die max principal stress as a function of applied tapper force, for the prior art lead frame of FIG. 1, the first modified lead frame of FIG. 6A, and the second modified lead frame of FIG. 11, encapsulated into the structures shown in FIGS. 16-18, respectively, showing measured tapper force to crack die for each type of lead frame, in accordance with one embodiment; and

FIG. 23 is a graph of simulation testing results, showing die max principal stress as a function of applied holder force, for the prior art lead frame of FIG. 1, the first modified lead frame of FIG. 6A, and the second modified lead frame of FIG. 11, encapsulated into the structures shown in FIGS. 16-18, respectively, showing measured holder force to crack die for each type of lead frame, in accordance with one embodiment.

The drawings are not to scale, emphasis instead being on illustrating the principles and features of the disclosed embodiments. In addition, in the drawings, like reference numbers indicate like elements.

### DETAILED DESCRIPTION

Before describing details of the particular systems, devices, and methods, it should be observed that the concepts disclosed herein include but are not limited to a novel structural combination of components and circuits, and not necessarily to the particular detailed configurations thereof. Accordingly, the structure, methods, functions, control and arrangement of components and circuits have, for the most part, been illustrated in the drawings by readily understandable and simplified block representations and schematic diagrams, in order not to obscure the disclosure with structural details which will be readily apparent to those skilled in the art having the benefit of the description herein. In addition, the following detailed description is provided, in at least some examples, using the specific context of integrated circuits that include Hall sensing elements, but this is merely exemplary and not limiting. It should be appreciated that such references and examples are made in an effort to promote clarity in the description of the concepts disclosed herein. Such references are not intended as, and should not be construed as, limiting the use or application of the concepts, systems, arrangements, and techniques described herein to use solely with these or any other systems.

In addition, it is noted that various connections are set forth between elements in the following description and in the drawings. These connections in general and, unless specified otherwise, may be direct or indirect, and this specification is not intended to be limiting in this respect. In this disclosure, a coupling between entities may refer to either a direct or an indirect connection. It should be understood that throughout the drawings, corresponding reference numerals indicate like or corresponding parts and features. As used herein, the term module, unit and/or element can be formed as processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

Additionally, use of the term “signal” in conjunction with this disclosure is not limited to analog and/or digital signals but rather is meant to denote as well (1) the mathematical description of any measurable phenomena in nature or in human-made systems and (2) the mathematically described function of one or more variable depending on one or more parameters. Examples of types of signals which are encompassed in the embodiments described herein include, but are not limited to, light intensity, voltage, pressure, electromagnetic radiation (including radio waves), magnetic field strength and electric field strength.

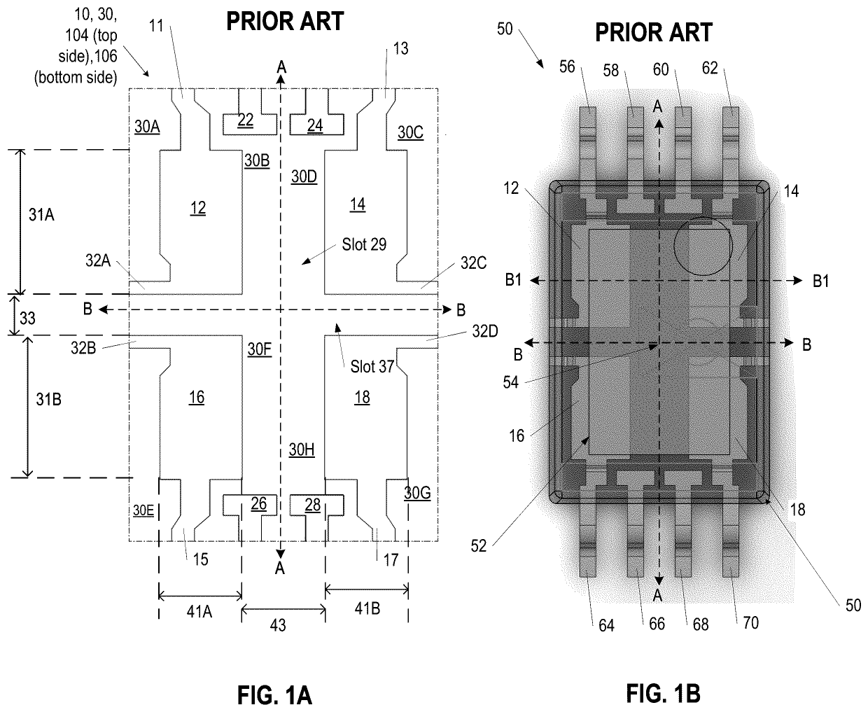

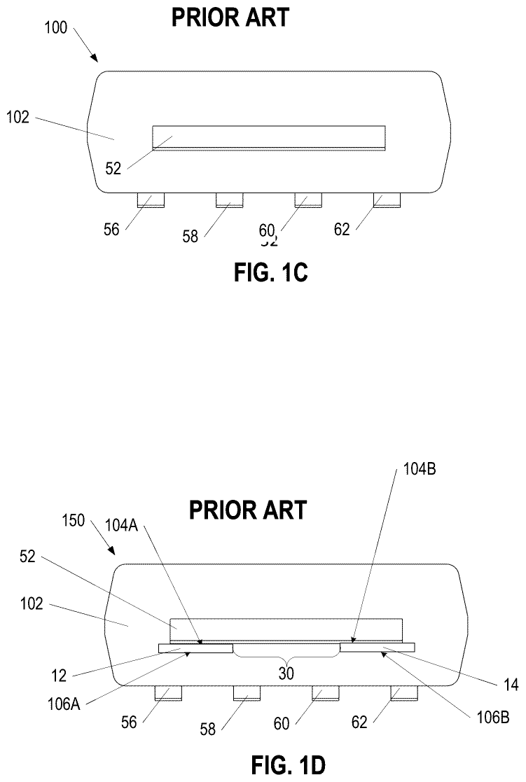

FIG. 1A illustrates a top view of portion of a first exemplary prior art lead frame 10, where the prior art lead frame 10 is configured for coupling to an exemplary first prior art semiconductor die 52 (FIG. 1B). FIG. 1B illustrates a top view of the exemplary first prior art lead frame of FIG. 1A operably coupled to the exemplary first prior art semiconductor die 52 and as assembled into a first prior art package 50. FIG. 1C is a cross-section view 100 of the first prior art package 50 of FIG. 1B, taken along the B-B line of FIG. 1B. FIG. 1D is a cross-section view 150 of the first prior art package of FIG. 1B, taken along the B1-B1 line of FIG. 1B.

Referring to FIGS. 1A-1D, the portion shown in FIG. 1A of the first exemplary prior art lead frame 10 can be part of an array (not shown) of lead frames that is patterned, stamped, etched, or otherwise formed out of a sheet or strip of electrically conductive material, such as a metal sheet, to form the desired lead frame features (e.g., signal leads, power leads, paddles, slots and other spaces) and the desired bends and other features (e.g., surface mount pads) in the leads 11, 13, 15, 17, and lead connection pads 22, 24, 26, 28. Generally, a plurality of lead frames like prior art lead frame 10 are formed from the same metal sheet. One or more tie bars (e.g., like tie bars 32 (e.g., first tie bar 32A, second tie bar 32B, third tie bar 32C, fourth tie bar 32D) hold together the lead frame 10 with other lead frames (not shown) in such an array. The thickness of the lead frame 10 can vary. In some embodiments the lead frame thickness is on the order of 20 mils, but this is not limiting.

The exemplary first prior art lead frame 10 of FIGS. 1A-1D includes four paddles 12, 14, 16, 18 by which the exemplary first prior art semiconductor die 52 is coupled to the first prior art lead frame 10, e.g., via adhesive, conductive tape, epoxy, solder, or other appropriate technique. In certain embodiments, each paddle 12, 14, 16, 18 is substantially planar and has a first side and a second opposing side. For example, as shown in the cross-section view 100 of FIG. 1D, first paddle 12 has a first side 104A and a second side106A; similarly, second paddle 14 has a first side 104B and a second side 106B. Although not visible in FIGS. 1A-1D, it will be appreciated, similarly, that third paddle 16 has a first side 104C and a second side 106D, and that fourth paddle 18 has a first side 104D and a second side 106D.

Referring particularly to FIGS. 1B, 1C and 1D, at a later stage of manufacture, the exemplary first prior art semiconductor die 52 can be attached to the lead frame 10 and then encapsulated, e.g., in a mold material. The exemplary first prior art lead frame 10 does not have a conventional contiguous die attach pad or area to which the exemplary first prior art semiconductor die 52 is attached, but rather the first prior art semiconductor die is attached to the paddles 12, 14, 16, 18 of at least four leads 11, 13, 15, 17, respectively, and thus to a non-contiguous surface. Accordingly, in some aspects, the lead frame 10 can be referred to as a “split lead frame” since there is not a contiguous die attach surface.

The first prior art lead frame 10 includes a first lead 11 with respective first paddle 12, a second lead 13 with respective second paddle, a third lead 15 with respective third paddle 16, and a fourth lead 17 with respective fourth paddle 18. The exemplary first prior art lead frame 10 also includes a plurality of pads for direct lead connections like first lead connection pad 22, second lead connection pad 24, third lead connection pad 26, and fourth lead connection pad 28. Direct connections can be made between the exemplary first prior art semiconductor die 52 and the leads (also known as lead connection pads) 11, 13, 15, 17, 22, 24, 26, 28, such as via one or more wire bonds (not shown in FIGS. 1A-1C). In addition, the leads (e.g., first lead 11, second lead 13, third lead 15, and fourth lead 17) also can connect directly to corresponding conductive portions on the exemplary first prior art semiconductor die 52, as will be understood and can be attached via an adhesive, such as a conductive adhesive, adhesive tape, epoxy, etc. The exemplary first prior art semiconductor die 52 also may be electrically coupled to the exemplary first lead frame 10 by various techniques, such as with solder bumps or wire bonding.

In some embodiments, if the exemplary first prior art semiconductor die 52 (FIG. 1B) is attached to the first prior art lead frame 10 across multiple leads, then one mechanism for attaching the exemplary first prior art semiconductor die 52 to the first prior art lead frame 10 is non-conductive adhesive that may take various forms, such as a non-conductive, electrically insulative adhesive, such as a thermoset adhesive (e.g., a two part epoxy), epoxy, tape, such as a Kapton® tape, or die attach film, but this is not limiting. Depending on the particular electrical needs in a given application, an electrically conductive adhesive may be used, as will be appreciated.

Once the resultant first prior art package 50 is formed (i.e., once the exemplary first prior art semiconductor die 52 is attached to the paddles 12, 14, 16, 18) and once internal electrical connections are made (e.g., by wire bonds or clips), then the resultant assembly of the lead frame 10 and exemplary first prior art semiconductor die 52 are encapsulated, such as being overmolded by plastic potting or mold material, to form the first prior art package 50. The resultant first prior art package 50 is separated (e.g., singulated) from other packages formed from the same array of lead frames 10, so that the first prior art package 50 can be used as part of an electrical circuit, e.g., on a circuit board, as is understood.

As FIGS. 1A, 1B, 1C and 1D illustrate, in the exemplary first prior art lead frame 10, there are various so-called separating features 30 (which also are referred to herein as slots 30, openings (e.g., slots 30, or spaces 30), e.g., first space 30A, second space 30B, third space 30C fourth space 30D, fifth space 30E, sixth space 30F, seventh space 30G, and eighth space 30H) between the various die attach portions (i.e., the paddles, die pads, leads, etc.) as well as between the tie bars 32. These openings (e.g., slots 30), in certain embodiments, create a discontinuity between the first surface of first side 604 and the second surface of second opposing side 606 of the first modified lead frame. The openings/slots 30 can be continuous (e.g., completely punched out through the first prior art lead frame 10) or can be formed as slots, grooves, etc., or other recessed areas, which do not go through the entire thickness of the first prior art lead frame 10, as will be understood. For example, one type of separating feature is further explained further in commonly assigned, U.S. Pat. No. 9,411,025 (hereinafter '025 patent) to David et al, which describes how various separating features (e.g., grooves, recessed portions, raised areas) between portions of the lead frames can help to prevent solder used to attach certain circuit elements from adversely impacting (e.g., flowing to) other electrically distinct elements. The '025 patent is hereby incorporated by reference.

Another type of separating feature advantageously is used to help reduce eddy currents in semiconductor dies that include circuit elements such as magnetic field sensing elements. As used herein, the terms “magnetic field sensing element” and “magnetic field sensor” are used interchangeably to describe a variety of electronic elements that can sense a magnetic field. As used herein, the term “magnetic field sensor” is used to describe a circuit that uses a magnetic field sensing element, generally in combination with other circuits. Magnetic field sensors are used in a variety of applications, including, but not limited to, an angle sensor that senses an angle of a direction of a magnetic field, a current sensor that senses a magnetic field generated by a current carried by a current-carrying conductor, a magnetic switch that senses the proximity of a ferromagnetic object, a rotation detector that senses passing ferromagnetic articles, for example, magnetic domains of a ring magnet or a ferromagnetic target (e.g., gear teeth) where the magnetic field sensor is used in combination with a back-biased or other magnet, and a magnetic field sensor that senses a magnetic field density of a magnetic field.

The magnetic field sensing element/magnetic field sensor can be, but is not limited to, a Hall effect element, a magnetoresistance element, or a magnetotransistor. As is known, there are different types of Hall effect elements, for example, a planar Hall element, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR, including spin-valve structures) element, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

As is known, some of the above-described magnetic field sensing elements tend to have an axis of maximum sensitivity parallel to a substrate that supports the magnetic field sensing element, and others of the above-described magnetic field sensing elements tend to have an axis of maximum sensitivity perpendicular to a substrate that supports the magnetic field sensing element. In particular, planar Hall elements tend to have axes of maximum sensitivity perpendicular to a substrate, while metal based or metallic magnetoresistance elements (e.g., GMR, TMR, AMR) and vertical Hall elements tend to have axes of maximum sensitivity parallel to a substrate.

In some embodiments, the exemplary first prior art semiconductor die 52 is configured to support the magnetic sensing element as well as other circuit elements, such as electronic components, and circuitry, as will be understood. These other circuit elements can be coupled to the lead connection pads 22, 24, 26, 28 by various techniques, such as solder balls, solder bumps, pillar bumps, wire bonds, etc. In some embodiments, if solder balls, solder bumps, or pillar bumps are used, the exemplary first prior art semiconductor die 52 may be attached to the paddles 12, 14, 16, 18F with an active surface of the exemplary first prior art semiconductor die 52 (e.g., in which a magnetic field sensor is disposed) so that the active die surface is adjacent to a surface of the first prior art lead frame 10, as in a flip chip arrangement.

If the semiconductor dies include magnetic field sensing elements such as Hall sensors, there may need to be modifications to the lead frame (which often is made from metal) to avoid impacting the magnetic field sensing functionality. As is known in the art, in the presence of an AC or transient magnetic field (e.g., a magnetic field surrounding a current carrying conductor), eddy currents can be induced in a lead frame made of conductive material. Eddy currents form into closed loops that tend to result in a smaller magnetic field. Consequently, a Hall effect element experiences a smaller magnetic field than it would otherwise experience, resulting in a less sensitivity. Furthermore, if the magnetic field associated with the eddy current is not uniform or symmetrical about the Hall effect element, the Hall effect element might also generate an undesirable offset voltage.

In some applications, e.g., as described in the various incorporated by reference patents herein), the lead frame separating features may include slots or complete openings below the semiconductor die, where the slots may help reduce Eddy currents that may be generated by one or more magnetic components that are part of the semiconductor die. An example of how to do this is described in commonly assigned and incorporated-by-reference U.S. Pat. No. 9,228,860 (hereinafter '860 patent), which is hereby incorporated by reference. As the '860 patent explains, in the presence of an AC magnetic field (e.g., a magnetic field surrounding a current carrying conductor), AC eddy currents can be induced in a conductive lead frame. Eddy currents form into closed loops that tend to result in a smaller magnetic field so that a magnetic element (e.g., a Hall effect element) experiences a smaller magnetic field than it would otherwise experience, resulting in a less sensitivity and/or an undesirable offset voltage.

Thus, slots, splits and other types of cutouts or alterations in the lead frame, can help to reduce a size (e.g., a diameter or path length) of the closed loops in which the eddy currents may travel in a lead frame. As is understood, a reduced size of the closed loops in which the eddy currents travel results in smaller eddy currents for a smaller local effect on the AC magnetic field that induced the eddy current. Also, slots can move the position of the eddy currents and also reduce a size (e.g., a diameter or path length) of the closed loops in which the eddy currents travel in the lead frame to result in a smaller magnetic field error so that a Hall effect element experiences a smaller magnetic field from the eddy currents than it would otherwise experience, resulting in less error in the measured field and enhanced overall performance of the sensor. The aforementioned, commonly assigned '860 patent describes various embodiments of sensor packages that include one or more slotted lead frames that can help reduce such eddy currents. In addition, the aforementioned '025 patent, as well as commonly assigned U.S. Pat. No. 9,494,660 (hereinafter '660 patent), to David et al., which are each hereby incorporated by reference, describe various embodiments of split lead frames.

Referring again to FIGS. 1A-1D, the separating features 30 (also referred to herein as slots 30 and/or spaces 30) of FIG. 1A, which provide breaks in the conductivity of the first prior art lead frame, also can be configured to help reduce a size (e.g., a diameter or path length) of the closed loops in which the eddy currents travel in the first prior art lead frame 10, and the locations of the breaks can be configured to substantially match the locations of corresponding magnetic elements (e.g., Hall elements) in the exemplary first prior art semiconductor die 52. For example, if a Hall sensor is used as a current sensor, advantageous location of the slots or other openings can help to ensure that the sensitivity of a current sensor having a Hall effect element is less affected by eddy currents due to the slot(s). Instead of an eddy current rotating about Hall effect element, use of a slot (or other space that breaks electrical continuity), results in eddy currents to each side of the Hall element. While the magnetic fields resulting from the eddy currents are additive, the overall magnitude field strength, compared to a single eddy current with no slot, is lower due to the increased proximity of the eddy currents.

As noted above, the slots 30 (i.e., 30A, 30B, 30C, 30D, 30E, 30F, 30G, 30H) provide spaces between the first paddle 12, second paddle 14, third paddle 16, and fourth paddle 18, wherein some of the separating features further define supported slot regions along lengths 31A, 31B and an unsupported slot region along the region shown as having a length 33, where the lengths run along a length parallel to the longest side of a rectangular die to be attached to the first modified lead frame 10. Some of these slots 30 combine along the A-A axis and/or the B-B axis to form larger slots. In this disclosure, a “supported slot region” is defined as a lengthwise portion of a slot in which, for the entire lengthwise portion, there is at least some lead frame support on both sides of the slot. The lead frame support in some instances can be along an axis perpendicular to the slot. The lead frame support in some instances can be at an angle to the slot. An “unsupported slot region,” in this disclosure, is defined as a lengthwise portion of a slot where there is no lead frame support on either side of the slot.

In accordance with the above characterizations, it can be seen that the first prior art lead frame 10 has slots that contain both supported slot regions and unsupported slot regions. For example, in FIG. 1A, there is a first slot 29 in the first modified lead frame that runs along the A-A axis (i.e., a vertical slot). First slot 29 has a width that is the same size as length 43 and has a length that is the same size as the total of the lengths 31A, 31B and 33. There is a first supported slot region along the length 31A, a first unsupported slot region along the length 33, and a second supported slot region along the length 31B. The length 33 includes the first unsupported slot region because it can be seen that along the length 33, there is no lead frame present along both sides of the first slot 29. That is, along the first slot 29 (vertical slot), there is a gap along the length, where the gap has a length the same as length 33, where along the gap there is no lead frame present along both sides of the first slot 29.

The first prior art lead frame 10 also includes a second slot 37 (horizontal slot) that runs along the B-B axis, where the second slot 37 effectively is perpendicular to the first slot 29. The second slot 37 has a width that is the same as length 33 (i.e., its shortest dimension) and a length, along the B-B axis, that is the same size as the total of the lengths 41A, 41B, and 43. For second slot 37, there is a third supported slot region along the length 41A, a second unsupported slot region along the length 43, and a fourth supported slot region along the length 41B. Similar to the first slot 29, it can be seen that, along the length 43, there is no lead frame present along both sides of the second slot 37, such that there is a gap along the horizontal length. As discussed further herein, this absence of lead frame may result in inadequate mechanical support from the first prior art lead frame 10, to a die that is mounted to the lead frame (e.g., as shown in FIG. 1B), when the first prior art lead frame 10 is under the die, leading to die cracking in some of the unsupported regions.

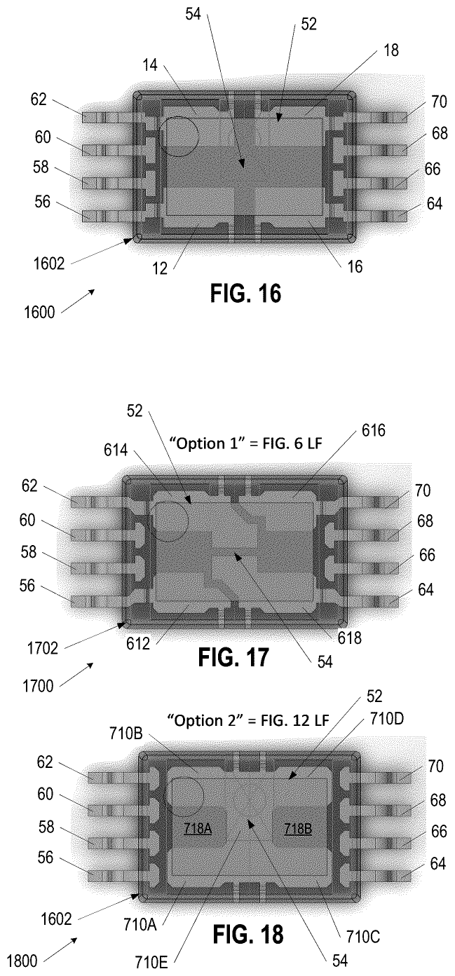

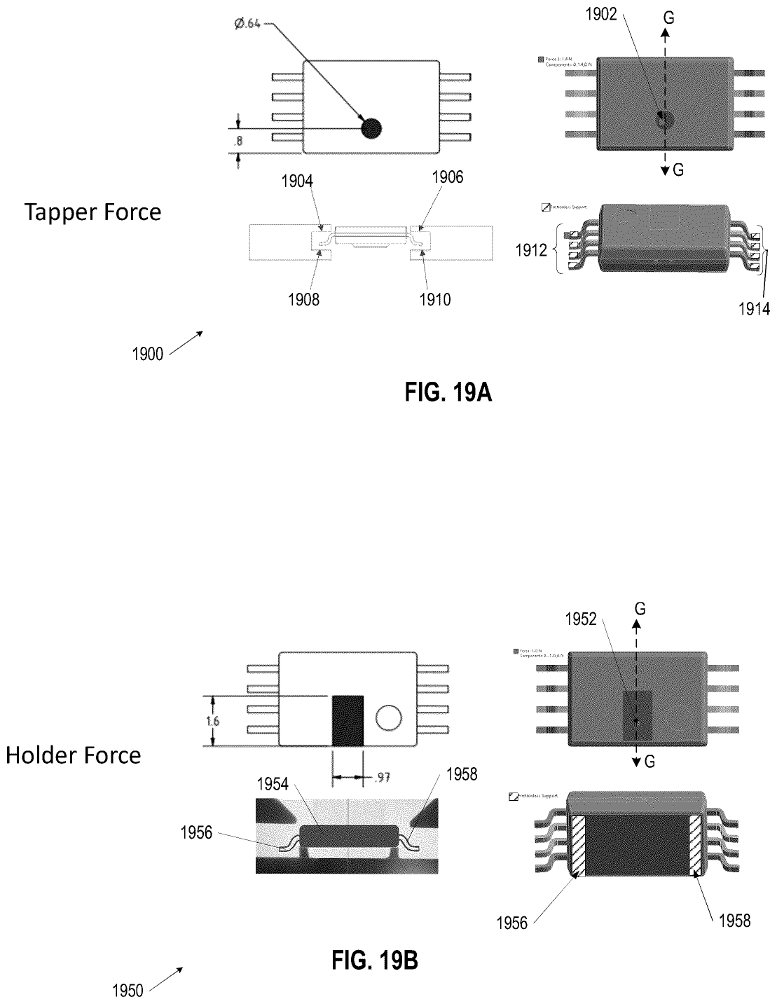

For first slot 29, the first unsupported slot region, defined along length 33, is much smaller than the supported slot regions defined by lengths 31A, 31B. The first unsupported slot region, defined by length 33, is a very small portion of the entire length of the slot, such that 85% or more of the length of the slot along the A-A axis, has at least some lead frame support along an axis perpendicular to the slot. In contrast, for second slot 37, which forms a horizontal gap along axis B-B, it can be seen that the second unsupported slot region, defined along length 43, corresponds to nearly a third of the total length of the second slot 37 (where this length does not include tie bars 32 as part of the slot length of second slot 37, as will be understood). For the second slot 37, only about 66% of the second slot has lead frame support along both sides of the slot, in contrast with the first slot 29, where about 85% of the first slot 29 has lead frame support along both sides of the first slot 29. As discussed further herein, the die cracking issue occurs along this B-B axis which is only ⅔ supported by lead frame and which has no lead support at either end, in contrast to along the A-A axis, which has support via the lead pins 56, 58, 60, 62, 64, 66, 68, 70 (e.g., as discussed further herein in connection with FIG. 19B, with lead support at connections 1956 and 1958), It is possible that lead frame designs having this larger area that lacks lead frame support and/or lead pin support, especially along the B-B axis, contributes to the die cracking issue. This may be true especially for dies with a high aspect ratio (i.e., where the short side of the die, running parallel to the B-B axis, is considerably shorter than the long side of the die, which runs parallel to the A-A axis). Furthermore, as discussed further herein in connection with the testing discussion of FIGS. 16-23, a large unsupported area, such as along the B-B axis, can put the die into a 3-point bend situation and make the die vulnerable to cracking, as further discussed below.

In addition, FIG. 1A also illustrates that there is a significant overlapping area between the slot that runs along the A-A axis and the slot that runs along the B-B axis, at a geometric center 54 of the first prior art lead frame 10, such that a significant region around the middle of the first modified lead frame 10 (and also around the middle of a die to be attached to it) has no lead frame support, which adds to vulnerability to cracking.

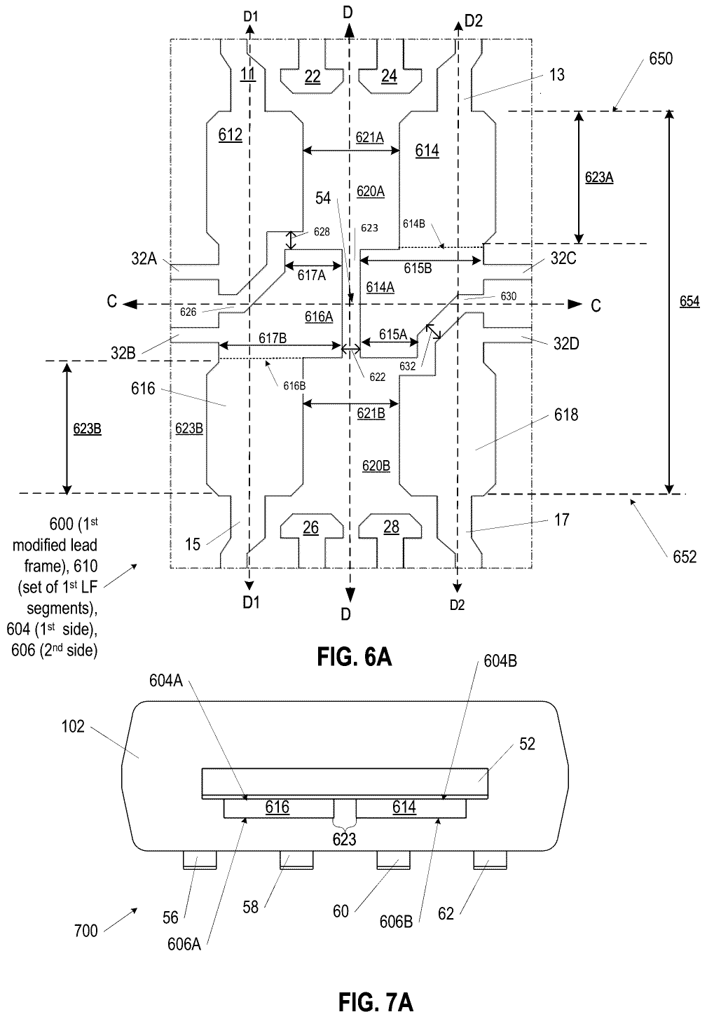

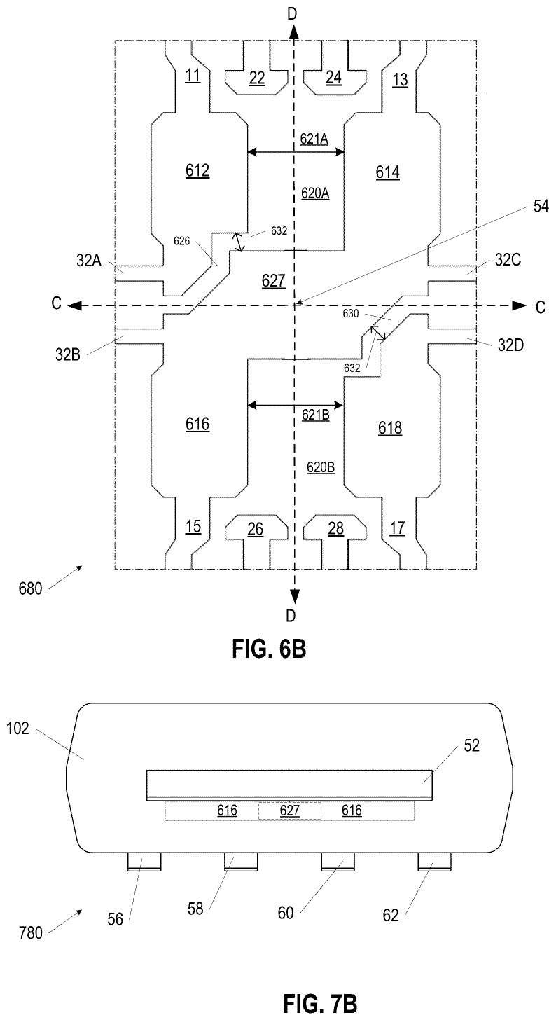

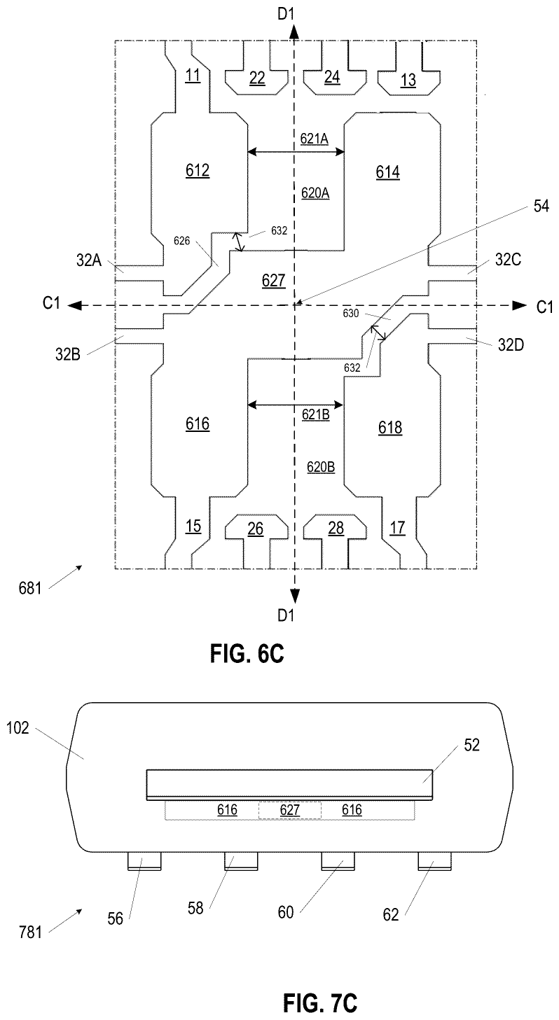

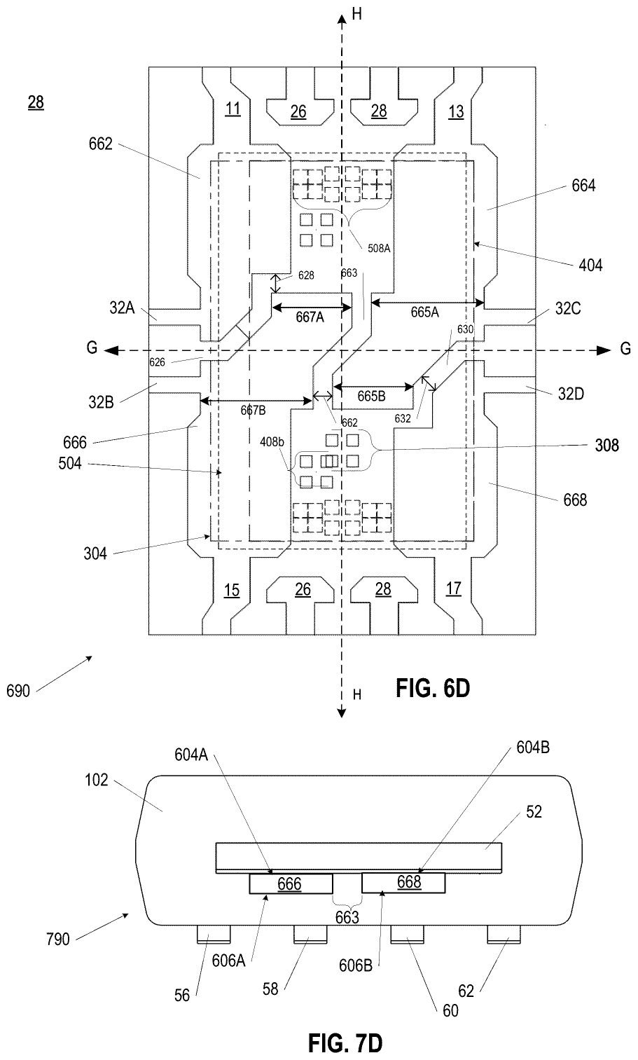

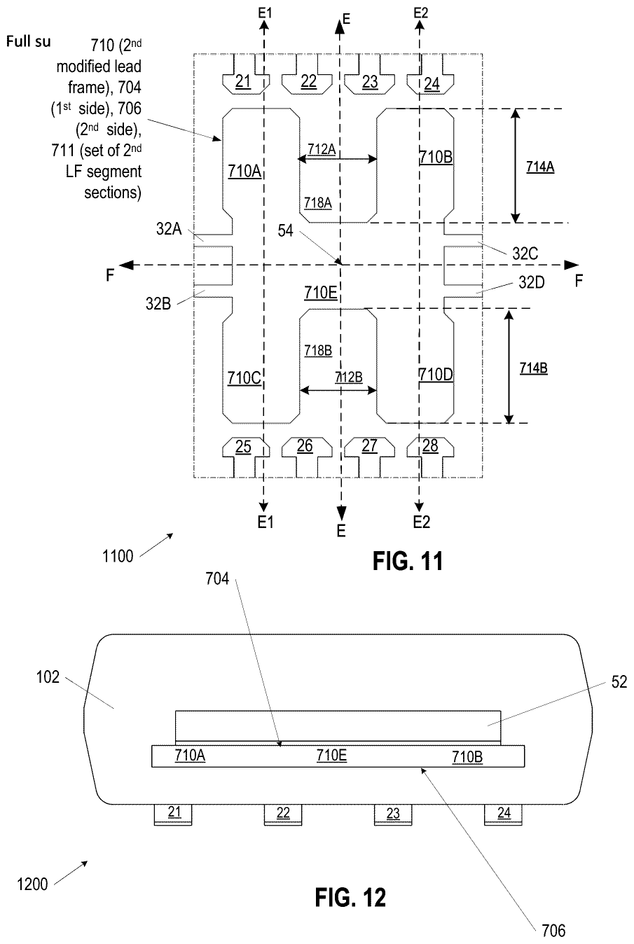

Another consideration with the second slot 37 is that not only does the second slot have more of its length unsupported by lead frame, but also the slot runs straight across the B-B axis (i.e., parallel to the short side of a die). It has been found that certain alterations to the design of the slot, discussed further herein, can help to reduce the die cracking issue. For example, in some modified designs, by offsetting the second slot 37 so that it does not run straight across the short side of the die (e.g., having the slot run diagonally), that die cracking along the short side may be reduced. This can be seen, e.g., in the embodiments of FIGS. 6A-10, discussed further herein. In some embodiments, by ensuring that the second slot 37 does not intersect or overlap with other slots (note that the second slot 37 overlaps with the first slot 29), that die cracking may be reduced. This can be seen both in the embodiments of FIGS. 6A-10, discussed further herein, as well as in the embodiments of FIGS. 11-15, discussed further herein. As will be discussed further herein in connection with the embodiments of FIGS. 6 and 11, and the simulation testing of FIGS. 16-23, these slot alterations of FIGS. 6A-15 did result in reduce die stresses, which are expected to lead to reduced die cracking.

It is understood that the term slot should be broadly construed to cover generally interruptions in the conductivity of the lead frame. For example, slots can include a few relatively large holes or spacings as well as smaller holes in a relatively high density. In addition, the term slot is not intended to refer to any particular geometry. For example, slots include a wide variety of regular and irregular shapes, such as tapers, ovals, etc. Further, it is understood that the direction of the slot(s) can vary. Also, it will be apparent that it may be desirable to position the slot(s) based upon the type, location, and/or number of magnetic field sensor(s). Advantageously, as the embodiments herein will discuss, the dimensions of a slot, the location of a slot, or the number of slots or other spaces can be formed in a wide variety of configurations to meet the needs of a particular applications or can be sized to be adaptable to a wide variety of semiconductor dies having Hall elements in various locations. As further discussed herein, in connection with the disclosed embodiments, the dimensions, location, and design of a slot can be tailored to both work with magnetic field sensing elements while also enabling the lead frame to maintain enough support for a die to minimize die cracking.

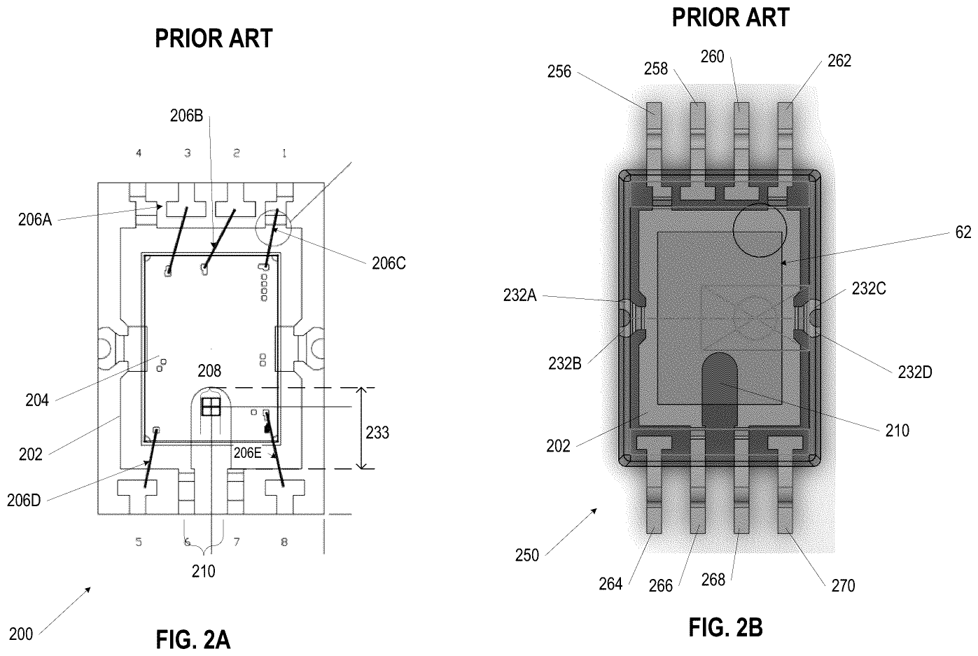

For example, FIG. 2A is a top view of a second assembly 200 that includes a second exemplary prior art lead frame 202 operably coupled to an exemplary second prior art semiconductor die 204 that includes a first magnetic field sensor 208. The exemplary second prior art semiconductor die 204 is operably coupled to the exemplary second prior art lead frame 202 via a plurality of wire bonds 206A, 206B, 206D, 206D, 206E. In addition, it can be seen that the second prior art lead frame 202, in addition to its own tie bars 232A, 232B, 232C, 232D, effectively is formed as a single paddle that is coupled to leads and die pads that are in operable communication with the pins 256, 258, 260, 262, 264, 266, and 268 of second prior art package 250. The second prior art lead frame 202 includes a slot 210 sized to ensure that it does not cover the first magnetic field sensor 208. It can be seen that the entire length of slot 210 constitutes a supported slot region, in accordance with the previous description, because the entire length of slot 210 (e.g., the length 233 as shown in FIG. 2A) has at least some support on both sides of the slot 210. FIG. 2B is a top view of the second assembly of FIG. 2A, showing the assembly after overmolding into a second prior art package 250.

The exemplary second prior art lead frame 202 of FIGS. 2A-2B is advantageous in that it provides support for the exemplary second prior art semiconductor die 204 everywhere other than in the slot 210, so this can help to reduce chances of mechanical damage to the exemplary second prior art semiconductor die 204 and/or the second prior art package 250. In addition, the second prior art lead frame 202 has a slot 210, which can be a custom slot, which is configured for ensuring that the eddy currents that might arise from the first magnetic field sensor 208 will flow along each side of the first magnetic field sensor 208, for a smaller local effect on the AC magnetic field that induced the eddy current. However, the exemplary second prior art lead frame 202 of FIGS. 2A-2B may not be suitable for use with all types of semiconductor dies, such as those having magnetic field sensors similar to first magnetic field sensor 208, but in in other locations, or having larger dimensions, or more than one magnetic field sensor, etc.

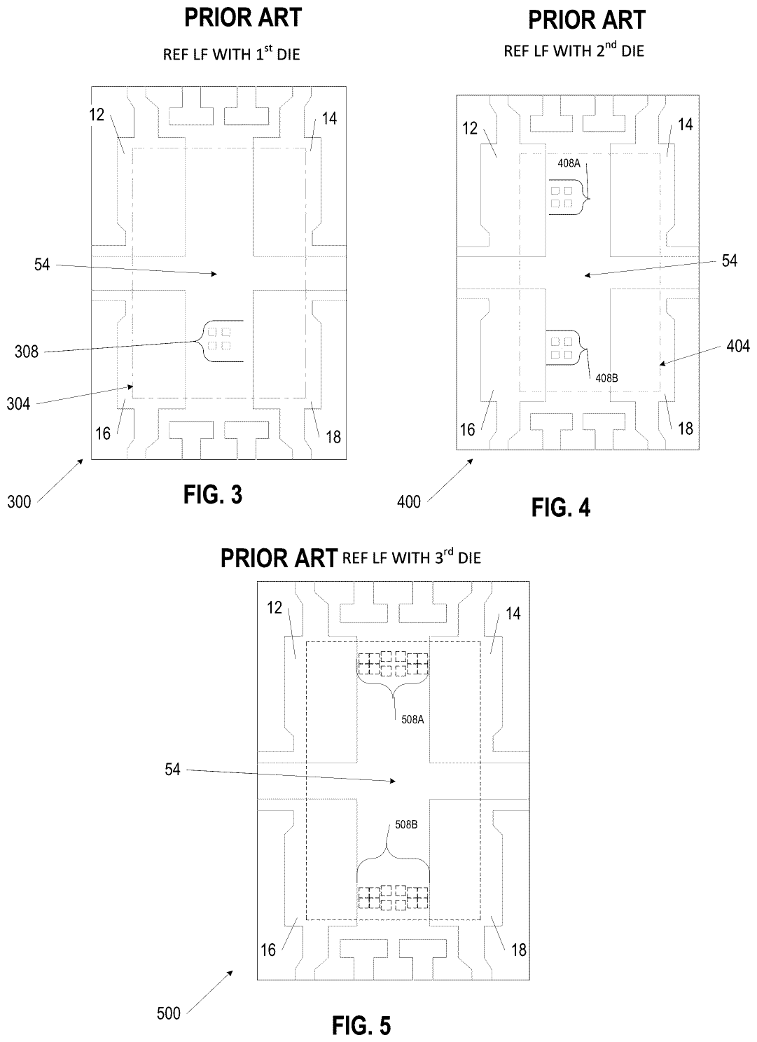

In contrast, the first prior art lead frame 10, with its larger slots along two axes, may be more adaptable for multiple different types of semiconductor dies, having varying sizes and varying locations of one or more magnetic field sensors. This can be seen in the exemplary prior art embodiments of FIGS. 3-5. For example, consider FIG. 3, which is a top view of a third prior art assembly 300, showing the first exemplary prior art lead frame 10 of FIG. 1A coupled to a first type of semiconductor die 304. As FIG. 3 shows, the first type of semiconductor die 304 includes a first magnetic field sensor 308 that is disposed at a location on the first type of semiconductor diet so that the first magnetic field sensor 308 is not covered by any of the paddles 12, 14, 16, 18 of the first exemplary prior art lead frame 10. That is, the third magnetic field sensor is located so that it is within a slot formed along the A-A axis (FIG. 1A) of the lead frame. Each paddle 12, 14, 16, 18 is configured so that it can be overlayed by at least a portion of the first type of semiconductor die 304. It can be seen that there is neither a magnetic field sensor nor any lead frame at the geometric center 54 of the first type of semiconductor die 304. In this example embodiment of FIG. 3, the first type of semiconductor die is constructed and arranged so that it overlays each paddle 12, 14, 16, 18 equally.

FIG. 4 illustrates an arrangement somewhat similar to that of FIG. 3 but with two magnetic field sensors, each disposed at opposite ends of the die; in some embodiments, this arrangement of two magnetic field sensors (e.g., Hall sensors), disposed at opposite ends of the die, is ref erred to as a symmetrical arrangement of magnetic field sensors. FIG. 4 shows a top view of a fourth prior art assembly 400 showing the first exemplary prior art lead frame 10 of FIG. 1A coupled to a second type of semiconductor die 404. As FIG. 4 illustrates, the second type of semiconductor die 404 includes such symmetrical magnetic field sensors, including a second magnetic field sensor 408A and a third magnetic field sensor 408B, where the second magnetic field sensor 408A and the third magnetic field sensor 408B are located within the slot formed along the A-A axis of the first prior art lead frame 10 (FIG. 1A), to help avoid interference with operations of the second magnetic field sensor 408A and third magnetic field sensor 408B. It can be seen that the second type of semiconductor die 404 does not equally overlay the paddles 12, 14, 16, 18 of lead frame 10: the second type of semiconductor die 404 overlays the paddles 14 and 18 more than it does the paddles 12 and 16.

FIG. 5 is a top view of a fifth prior art assembly 500 showing the first exemplary prior art lead frame 10 of FIG. 1A coupled to a third type of semiconductor die 504, having a fourth magnetic field sensor 508A and a fifth magnetic field sensor 508B, both located so as to overlay the slot formed along the A-A axis of lead frame 10. Like the second type of semiconductor die 404, the third type of semiconductor die 504 includes symmetrical magnetic field sensors, but this is not limiting. It can be seen that the width of the slot along the A-A axis is sufficient to accommodate the width of the fourth magnetic field sensor 508A and fifth magnetic field sensor 508B, which are wider than the magnetic field sensors of FIGS. 3 and 4. The third type of semiconductor die 504 of FIG. 5, like the first type of semiconductor die 304 of FIG. 3, overlays the paddles 12, 14, 16, 18 equally.

The first prior art lead frame 10 of FIGS. 1A-1D and FIGS. 3-5 can be advantageous in some applications because the slots formed along the A-A and B-B axes (e.g., slot 30) are configured to ensure that they work with semiconductor dies having their magnetic field sensors in multiple locations, or which have magnetic field sensors of various sizes, as shown in FIGS. 3-5. Use of slots, splits, or cutouts may help to ensure that the sensitivity of a current sensor having a Hall effect element will be less affected by eddy currents, and use of a larger size of slot enables a lead frame to work with a greater variety of die packages. However, it has been found that, in some instances, certain lead frames having slots, splits, and/or cutouts may unintentionally be creating other issues for the semiconductor dies to which they are operably coupled, especially due to arrangements where the aforementioned unsupported slot regions can be too large or where their locations coincide with areas where a given die or package is stressed during handling.

For example, it has been found that some die problems are occurring in some existing lead frame (LF) designs for semiconductor packages that include magnetic sensing devices (position, speed, current) and which have lead frames that utilize slots, cutouts, and/or splits (e.g., to minimize magnetic reluctance & eddy currents and mitigate electrostatic discharge (ESD)). Specifically, some semiconductor packages which are manufactured using certain types of lead frames, have exhibited die crack issues during down-stream test handling. In some instances, this die cracking can manifest from process variations together with inadequate mechanical support from the lead frame under the die. In some instances, the cracking issue is more pronounced in semiconductor devices having a high aspect ratio (i.e., which are rectangular but have a relatively large size difference between the longer pair of sides (“length”) and the shorter pair of sides (“width”), e.g. with a length that is at least double the width.

For example, some die cracking has occurred along a short axis of a rectangular die (i.e., along a horizontal axis parallel to the two shorter sides of a rectangular shaped die package), in an area where there is no lead frame support. In some instances, the lead frames that are part of the die packages experiencing cracking, are configured similar to the first prior art lead frame 10 of FIG. 1A, where the cracking is occurring along the B-B axis (FIG. 1A, FIG. 1B), but was not seen to occur along the B1-B1 axis (FIG. 1C). Note that, as shown in FIGS. 1A-1D, is that there are areas along the first cross section line A-A, second cross section line B-B, and second parallel cross-section line B1-B1, where there is no lead frame 10, including at the geometric center 54 of the die (e.g., the slot 30 area, as shown in FIGS. 1A-1C) and along the slot 30. Thus, when a semiconductor die is attached to the lead frame, these areas are either only partially supported by the lead frame (e.g., along second parallel cross-section line B1-B1) or are not supported by any lead frame (along the axis B-B). Even though the slots are there to help reduce impacts on magnetic field sensors, the slots can create some issues that need to be mitigated. The lack of support under the center of the semiconductor die appears to be a contributing factor to the die cracking issue.

The lack of support can be seen more particularly in FIG. 1C, which is a cross-section view 100 of the first prior art package 50 of FIG. 1B, taken along the B-B line of FIG. 1B, including in comparison with FIG. 1D, which is a cross-section view 150 of the first prior art package 50 of FIG. 1B, taken along the B1-B1 line of FIG. 1B. As these two cross sections illustrate, there is no lead frame at all under the exemplary first prior art semiconductor die 52 in the area along the B-B line (which falls in an “unsupported slot region”), because the B-B line falls along a slot formed in the first prior art lead frame 10 which has at least some areas (e.g., the length 43) where there is not lead frame support on both sides of the slot along that length. In other cross sections, such as the view of FIG. 1D (taken along the B1-B1 axis of FIG. 1A), there is still some support, but there is still a significant gap in support as shown by the slot 30. However, the first prior art package 50 did not experience cracking along the B1-B1 axis along the lengths 31A and 31B, where there was some lead frame support; note that these correspond to supported slot regions.

At least some embodiments herein help to address at least some of these challenges, including by providing modified lead frame designs (as discussed further herein in connection with FIGS. 6 and 11), where the modified lead frame designs provide greater and/or increased support in areas under a die that are more prone to cracking, including along the horizontal or shorter axis, while still providing features, such as one or more slots, to help minimize negative impacts to any magnetic sensing devices that might be part of the semiconductor die. At least some embodiments are configured to provide improved die support while still including strategically designed slots and/or cutouts, where these slots/cutouts still provide the advantageous feature of minimizing magnetic reluctance, eddy currents, and ESD, while providing enough support for the semiconductor die to reduce die cracking. At least some embodiments herein are configured to minimize unsupported slot regions and maximize supported slot regions.

In some embodiments, a magnetic field sensor is provided with an improved lead frame design that ensures that there is sufficient lead frame support to reduce die cracking. To help accomplish this, in certain embodiments, lead frames are provided that provide at least some lead frame support, in a horizontal direction (e.g., a lateral direction) running parallel to the shortest side of the die to be coupled to the lead frame. In certain embodiments, the lead frame support is provided along a predetermined length of the die, advantageously a majority of the length, and in some embodiments all of the length, of the die to be attached. There are multiple embodiments discussed and illustrated herein that provide such improved lead frame designs. In some embodiments, the slots on the lead frame are configured so that, when a die is attached, there is still at least some lead frame support between the first side or end of the width and the second side or end of the width, for the entire length of the die. For example, in some embodiments, the lead frame and its one or more slot(s) are configured so that, at every width axis of the die, at least some predetermined amount, e.g., 50%, of that width axis supported by lead frame. In some embodiments, the lead frame is configured so that, within or along a predetermined length (or a predetermined set of width axes) of the die (which in some embodiments includes a majority of the length of the die), that at least some predetermined amount, e.g., 50%, of the die, from the first side or end of the width to the second side or end of the width, is supported by the lead frame.

In some embodiments, the lead frame is configured so that there is at least one axis that is parallel to the shortest side (i.e., width axis) of a die to be attached, where the die is fully supported by the lead frame. In some embodiments, the lead frame is configured so that there are no slots that run straight across the width of a die to be supported by the lead frame. In some embodiments, the lead frame is configured so that any slots that have a horizontal portion do not run in a horizontal direction for the entire length of the slot.

Various embodiments implemented herein, including at least some embodiments of the modified lead frame designs of FIGS. 6 and 11 (discussed further below), can provide some or all of the above-listed improved lead frame design and above-listed lead frame features, as will be understood from the below description and from the drawings. In certain embodiments, these improved lead frame designs provide the advantageous stronger mechanical support under the die to minimizing and/or eliminating the risks of die cracking, while also insuring the required reduced magnetic reluctance & eddy currents and mitigate ESD for optimum sensor performance. At least some embodiments herein help to improve mechanical robustness of the die. In some embodiment (e.g., the “full support” lead frame embodiment of FIG. 11, discussed further herein), the central pad is disconnected from all leads, which can impact ESD performance. In at least some embodiments (e.g., the segmented lead frame option of FIGS. 6A-6D). the original pin connections (of the prior art) are maintained, to help enhance and maintain ESD performance.

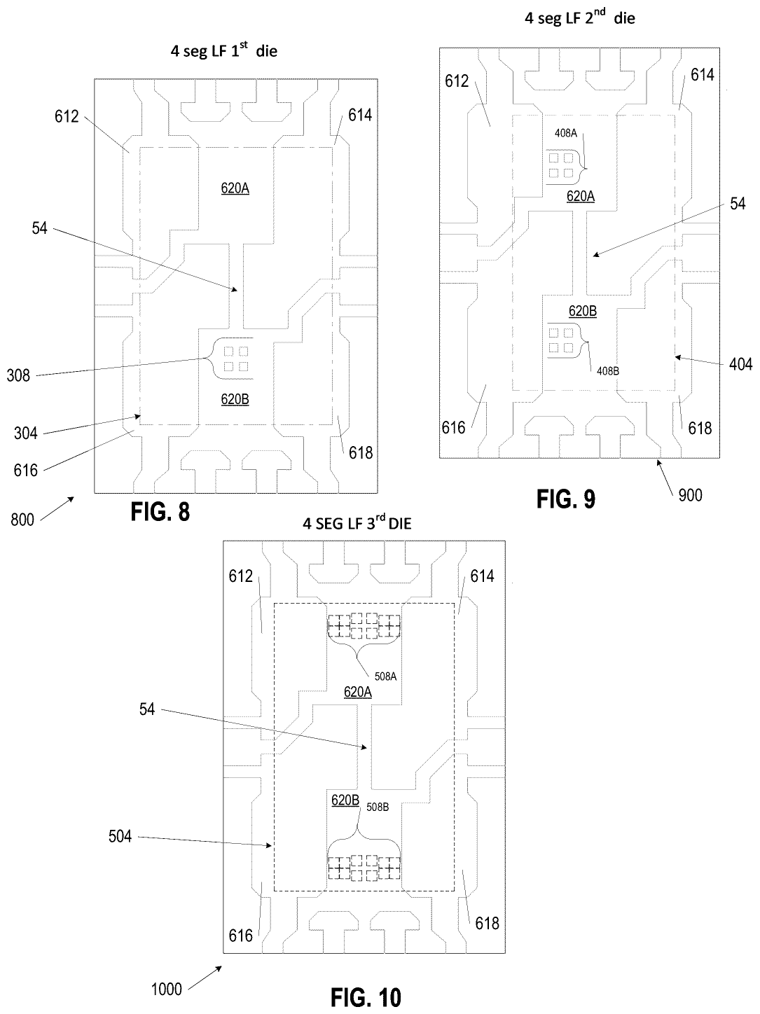

FIG. 6A is a top view of a portion of a first modified lead frame 600, in accordance with one embodiment. The first modified lead frame 600 of FIG. 6A illustrates a horizontal axis, the C-C axis, where the horizontal axis is parallel to the shortest side of a die (e.g., as shown in FIGS. 8-10) to be coupled to the lead frame. As FIG. 6A illustrates, the first modified lead frame 600 provides lead frame support along a substantial length of the lead frame, e.g., along nearly all of the length, along the D-D axis (vertical axis) that runs parallel to the longest side of a die (e.g., as shown in FIGS. 8-10) to be attached to the first modified lead frame 600. In certain embodiments, as FIG. 6A illustrates, in the portion of the first modified lead frame 600 that lies between a first end defined at line 650 and second end defined at line 652, i.e., along the entire length defined by length 654, every horizontal axis along the line 652 has at least a first predetermined amount, e.g., at least 25%, of the width having lead frame support. In certain embodiments, most of the length 654 has at least a second predetermined amount, e.g., at least 50%, of the width having lead frame support. For example, in one illustrative embodiment, referring to FIG. 6A, the gap 621b is approximately 0.8 mm and an overall width of a given die (e.g., from the D1-D1 axis to the D2-D2 axis) is 1.92 mm, and the third slot spacing 622 is 0.15 mm. Thus, it can be seen that, for a die having a width of 1.92 mm, along the C-C axis, there is a minimum of 58.33% lead frame support (e.g., along the portion adjacent to the gap 621b) up to as much as 92% lead frame support. Even with the slots and spacings configured to cooperate with the magnetic field sensing devices (as discussed further below), in certain embodiments, there is at least a third predetermined amount, e.g., at least 50%, of lead frame support in the horizontal direction parallel to the C-C axis, along most or at least a significant portion of the length of the lead frame. Advantageously, in certain embodiments of FIG. 6A, when coupled to a die, there is no horizontal axis that lacks lead frame support somewhere along the horizontal axis, even when the lead frame includes at least one lengthwise/vertical slot or spacing where there is no lead frame along the length of the vertical slot, e.g., as shown in FIG. 6A along the D-D axis.

Referring to FIG. 6A, the first modified lead frame 600 also is referred to herein as the “four segment” lead frame design and advantageously is formed using an electrically conductive material, such a metal, but this is not limiting. Depending on the needs of a given application, including the particular layout of pins to be operably coupled to a given die it is possible that one or more portions of the first modified lead frame 600 may be formed using a material that is not electrically conductive. The first modified lead frame 600 can be formed in any manner known in the art or later developed, including but not limited to patterning, stamping, etching, etc., out of a sheet or strip formed from one or more materials (e.g., electrically conductive material) to form the desired lead frame features. In at least some embodiments, a plurality of lead frames 600 may be formed, e.g., as a strip or an array, from the same sheet of material. The lead frame 600 is configured to be connected to other lead frames in an array or strip, via first tie bar 32A, second tie bar 32B, third tie bar 32C and fourth tie bar 32D, in a manner similar to that described above for the first prior art lead frame 10 of FIG. 1A. The tie bars not only help during manufacturing of the first modified lead frame 600, but also can help to protect the first modified lead frame 600, its leads, and/or its die support sections, during handling, for example, by helping to maintain coplanarity of the features of the first modified lead frame 600.

The thickness of the first modified lead frame 600 can vary based on the application; an exemplary thickness of the first modified lead frame 600 is approximately 20 mils, but this is not limiting. The first modified lead frame 600, in certain embodiments, is substantially planar and has a first side 604 and a second opposing side 606, which sides are more visible in the cross section view of FIG. 7A, discussed further herein. Many different materials are usable for the first modified lead frame 600, as will be appreciated. In one embodiment, the first modified lead frame is a copper lead frame plated with NiPdAu (nickel-palladium-gold), but this is not limiting. The first modified lead frame 600 can be made with and/or plated with many different materials, including but not limited to copper, copper alloys, pure or low-alloy nickel materials (e.g., alloy-42, which is alloy of iron and nickel with 42% nickel), various proprietary materials such as EFTEC 64T (a copper substrate material made from copper, zinc, tin, and chromium and plated with silver, available from Fine Optonics Corporation of Saitama, Japan), etc. In some embodiments, the first modified lead frame 600 may be formed using one or more other suitable materials, including but not limited to aluminum, titanium, tungsten, chromium, Kovar™, or alloys of the metals, including in combination with nickel and/or copper. In some embodiments, the first modified lead frame 600 may be comprised of a non-conductive substrate material, such as a standard PC board with FR-4 and copper traces, or a Kapton material with copper or other metal traces (for example a flexible circuit board), or other non-conductive material with appropriate electrically conductive patterns applied that together form portions of or the entirety of a lead-frame type of structure.

Referring again to FIG. 6A, the first modified lead frame 600 maintains the basics of a type of four-segment lead frame design configuration that the prior art lead frame 10 of FIG. 1A has, but, as FIG. 6A makes very clear, the first modified lead frame 600 provides four segments that are arranged quite differently and also extend further along the lengthwise (vertical) and widthwise (horizontal) axes of the lead frame 600, while still providing not only larger slots/cutouts to provide spacing around areas that overlay magnetic sensing devices, but also smaller slots/cutouts to further reduce negative impacts, such as eddy current loops. In particular, in at least some embodiments, segments of the first modified lead frame are shaped, constructed, and arranged so that, along the C-C axis (a horizontal axis that is, in certain embodiments, is intended to align substantially along the middle of a die to be attached, along a horizontal axis of the die), most, but not all, of the C-C axis is supported by the first modified lead frame 600, wherein the areas that are not supported by lead frame are part of slots formed within the first modified lead frame. In certain embodiments, these slots are configured to help minimize negative impacts to at least one magnetic sensing device that is part of a die to be attached to the lead frame. Thus, the four segments of FIG. 6A provide additional advantages and features not present in the first prior art lead frame of FIG. 1A. In addition, the first modified lead frame 600 of FIG. 6 keeps the number of leads (eight leads) and pin connections the same as the prior art lead frame 10 of FIG. 1A, which is advantageous for compatibility with the same chip designs with which the first prior art lead frame 10 was used, but this is not, of course, required, as will be understood. For example, as will be discussed further herein in connection with the alternate embodiments of FIGS. 6C and 6D, in some embodiments, the leads and/or pin connections can vary from those of the prior art lead frame 10 of FIG. 1A, and in some embodiments, one or more segments of the lead frame may not be connected to any leads or pins.

Providing the multi segment style of design, e.g., the four segment design of FIG. 6A and/or the three segment designs of FIGS. 6B and 6C, including some slots between the segments/paddles, and optionally similar pin connections, as discussed herein and below, helps help to enhance ESD performance for some applications, as well, by ensuring that the lead frame layout, especially of the segments/paddles connected to the leads, remain electrically isolated from each other, if a given application requires it. In addition, the first modified lead frame 600 has much smaller gaps between its different lead frame segments compared to the first prior art lead frame 10 of FIG. 1A, which helps to provide better robustness to the lead frame, while improving ESD robustness during manufacture, processing, and test. This is explained further below.

Referring to FIG. 6A, the first modified lead frame 600 includes a first lead frame (LF) segment 612 (similar to a paddle) that is coupled to a first lead 11, a second LF segment 614 connected to second lead 13, a third LF segment 616 connected to third lead 15, and a fourth LF segment 618 connected to fourth lead 17. For brevity, the combination of the first LF segment 612, second LF segment 614, third LF segment 616, and fourth LF segment 618, will be referred to herein as the set of first LF segments 610. Each LF segment serves as a die attach portion of the first modified lead frame 600, as will be appreciated. The first modified lead frame 600 also includes first lead connection pad 22, second lead connection pad 24, third lead connection pad 26, and fourth lead connection pad 28. The leads and lead connection pads in the first modified lead frame 600 are similar to those described above in connection with the first prior art lead frame 10 of FIG. 1A, but this arrangement is not limiting.

Direct connections can be made a semiconductor die that is to be attached to the first modified lead frame 600 via the set of first LF segments 610 and via the leads and/or connection pads 11, 13, 15, 17, 22, 24, 26, 28, such as via one or more wire bonds (not shown). In addition, the set of first LF segments 610 and/or the leads (e.g., first lead 11, second lead 13, third lead 15, and fourth lead 17) also can connect directly to corresponding conductive portions on a semiconductor die (e.g., those shown in FIGS. 8-10, discussed further below) and can be attached to the die via an adhesive, such as a conductive adhesive, adhesive tape, epoxy, etc. A semiconductor die also may be electrically coupled to the modified first lead frame 600 by various techniques, such as with solder bumps or wire bonding. The leads 11, 13, 15, 17 and/or lead connection pads 22, 24, 26, 28 can be configured to couple to pins (not shown) that are suitable to make electrical connection to electronic systems and components (not shown) that are outside of a resultant integrated circuit package (e.g., as shown in FIG. 17, which is discussed further herein).

The set of first LF segments 610 are configured to provide substantial support along the horizontal C-C axis which bisects the middle of the first modified lead frame 600, parallel to its shortest sides, and also along the vertical D1-D1 and the D2-D2 axes, which are each parallel to the D-D axis, which approximately bisects the middle of the first modified lead frame 600 in a direction parallel to its longest sides. The first LF segment 612 and the third LF segment 616 are configured to be in substantial alignment along the D1-D1 axis and are separated by a first slot 626 having a first slot spacing 628. The first slot 626 is shown as being configured to be substantially “above” the C-C axis, so as to allow a significant portion (i.e., third projecting portion 616A, defined by third dotted line 616B) to provide support along the C-C axis. The first slot 626 has one end that goes straight along horizontal axis C-C but then the first slot 626 angles upward before becoming vertical, and then horizontal again, as shown in FIG. 6A. The third projecting portion 616A has a third top projecting width 617A and a third bottom projecting width 617B, which help to define the first slot 626.

The contours of the first LF segment 612 and third LF segment 616 are configured to have a mating shape, along the first slot 626, wherein the mating shape is configured to maintain consistency of the first slot spacing 628. The mating shape shown in FIG. 6A is not, of course, limiting, and may take various forms, as will be understood. Further, the first slot spacing 628 is shown to be identical in size along the length of the first slot 626, but this is not limiting; as one of skill in the art will appreciate, the first slot 626 could be tapered or otherwise have variations along its length, so long as some spacing or separation is maintained between the first LF segment 612 and the third LF segment 616. In addition, the location, orientation, and size of the first slot 626 is selected so that, when a die is attached (e.g., as shown in FIGS. 8-10), there is still lead frame support from one side of the width of the die to the other side of the width of the die, for the entire length of the first slot 626. The first slot 626 does not include any unsupported slot regions.

Similar to the configuration of the first LF segment 612 and third LF segment 616, the second LF segment 614 and fourth LF segment are configured to be in substantial alignment along the D2-D2 axis and are separated by a second slot 630 having a second slot spacing 632. The second slot 630 is shown as being configured to be substantially “below” the C-C axis, so as to allow a significant portion (i.e., second projecting portion 614A, defined by second dotted line 614B) to provide support along the C-C axis. The second slot 630 has one end that goes straight along horizontal axis C-C but then the second slot 630 angles downward before becoming vertical, and then horizontal again, as shown in FIG. 6A. The second projecting portion 614A has a second top projecting width 615B and second bottom projecting width 615A, which helps to define the second slot 630.

The contours of the second LF segment 614 and fourth LF segment 618 are configured to have a mating shape, along the second slot 630, wherein the mating shape is configured to maintain consistency of the second slot spacing 632. The mating shape shown in FIG. 6A is not, of course, limiting, and may take various forms, as will be understood. Further, the second slot spacing 632 is shown to be identical in size along the length of the second slot 630, but this is not limiting; as one of skill in the art will appreciate, the second slot 630 could be tapered or otherwise have variations along its length, so long as some spacing or separation is maintained between the second LF segment 614 and the fourth LF segment 618. In addition, the location, orientation, and size of the second slot 630 is selected so that a die is attached (e.g., as shown in FIGS. 8-10), there is still lead frame support from one side of the width of the die to the other side of the width of the die, for the entire length of the second slot 630. The second slot 630 does not include any unsupported slot regions.

In the example embodiment of FIG. 6A, the first slot spacing 628 is the same as the second slot spacing 632, but this is not limiting. As can be seen in FIG. 6A, the first LF segment 612 is configured to have a similar overall shape as the fourth LF segment 618 but rotated 90 degrees. Similarly, the second LF segment 614 is configured to have a similar overall shape as the third LF segment 616 but rotated 90 degrees.

As noted above, two of the LF segments in the set of first LF segments 610, i.e., the second LF segment 614 and the third LF segment 616, are configured to have respective projecting portions 614A and 616A that project towards the geometric center 54 of the first modified lead frame 600. These respective projecting portions 614A, 616A are disposed along the C-C axis that lies along the middle of the first modified lead frame, parallel to its shortest sides (i.e., horizontal width) and are provided to help provide additional lead frame support, along that C-C axis, to a die that is connected to the first modified lead frame.

As discussed above in connection with the first prior art lead frame 10, recall that the axis C-C was the axis along which the most significant die cracking occurred. In the example embodiment of FIG. 6A, the third top projecting width 617A is shown to be the same as the second bottom projecting width 615A, but this is not limiting. Similarly, the third bottom projecting width 617B is shown to be the same as second top projecting width 615B, but this is not limiting. Those of skill in the art will appreciate that, if cracking is occurring along a specific axis that is different than the C-C axis, but parallel to the C-C axis, i.e., a particular axis of weakness, then the embodiment of FIG. 6A may be modified to have the projecting portions 614A, 616A to be located along the particular axis of weakness. As those of skill in the art will appreciate, because of the aspect ratio, cracking is not likely to take place along the D-D axis (or any axis parallel to the D-D axis). However, based on needs of the application, one of skill in the art will appreciate that the embodiment of FIG. 6A could be implemented so that its gap (third slot 623) is rotated +90 degrees or −90 degrees, as applicable, to provide similar support in that direction.

In addition, the third projecting portion 616A and the second projecting portion 614A are separated by a third slot 623 having a third slot spacing (width) 622. The third slot 623 runs along the central axis D-D of the first modified lead frame 600, parallel to the longest side of the first modified lead frame 600. The central axis D-D of FIG. 6A is substantially perpendicular to the axis C-C that runs parallel to the shortest side of the first modified lead frame 600, but this is not limiting. It will be understood that the third slot 623 alternately could be disposed so that it is on either side of the central axis D-D, and the third slot 623 alternately could be at an angle (e.g., could run diagonally, e.g., as shown and discussed herein in connection with FIG. 6D), where the orientation of the third slot 623 is selected to minimize at least one current loop associated with one or more magnetic sensing elements on a die that is attached to the first modified lead frame 600. The third slot 623 leaves an area around the geometric center 54 of the first modified lead frame 600 uncovered by lead frame, but still enables a significant amount of the axis C-C to have support in the first modified lead frame 600.

For example, in certain embodiments, the third slot 623 has a third slot width 615 and a third slot length 619, and the combination of the third slot width 615 and the size of the first projecting portion 614A and third projecting portion 616A is configured so that, along the third slot length 619, some predetermined amount of lead frame is present in the horizontal direction for all of the third slot length 619. The contours of the second LF segment 614 and third LF segment 616 are configured to have a mating shape, along the third slot 623, wherein the mating shape is configured to maintain consistency of the third slot spacing 622. The mating shape shown in FIG. 6A is not, of course, limiting, and may take various forms, as will be understood. Further, the third slot spacing 622 is shown to be identical in size along the length of the third slot 623, but this is not limiting; as one of skill in the art will appreciate, the third slot 623 could be tapered or otherwise have variations along its length, so long as some spacing or separation is maintained between the second LF segment 614 and the third LF segment 616. In addition, the location, orientation, and size of the third slot 623 is selected both to minimize eddy currents and also so that for a die is attached (e.g., as shown in FIGS. 8-10), there is still lead frame support from one side of the width of the die to the other side of the width of the die, for the entire length of the third slot 623. Thus, there is no unsupported region along the length of the third slot 623.

The configuration shown in FIG. 6A and described above, for the first prior art lead frame 600, stands in direct contrast to the first prior art lead frame 10, which effectively has a slot that runs along the entire vertical A-A axis but where there is at least some length of the slot (shown in FIG. 1A as length 33 having an unsupported region) where there is no lead frame support. In contrast, along the third slot length 619, there are portions of the first modified lead frame 600 along either side of the entire third slot length 619. In certain further embodiments, for the entire third slot length 619, the first modified lead frame 600 is configured so that there is lead frame supporting along any horizontal axis parallel to the shortest side of a die (which axis is referred to herein as a “horizontal parallel axis”) to be attached to the first modified lead frame 600. For example, in some embodiments, along the third slot length 619, a predetermined amount, e.g., at least 25%, of every horizontal parallel axis has lead frame support. The predetermined amount can vary based on the third slot width, third slot length 619, as will be appreciated. In some embodiments, along the entire third slot length 619, at least 50% of every horizontal parallel axis has lead frame support. In some embodiments, there can be lead frame support along less than 100% of the third slot length 619, as long as, for at least some predetermined portion of the third slot length (e.g., at least 25%, and advantageously at least 50%) of a lead frame of any axis in parallel with the C-C axis (including the C-C axis as well itself), there is lead frame.

In addition, even with the third slot 623, the strength of a die supported by the first modified lead frame 600 is not impacted negatively, because the third slot 623 runs parallel to the longer side of the die, and the die tends to be stronger in its longer direction, and more resistant to cracks. With the addition of the third slot 623, the entire axis D-D of the lead frame is uncovered, yet there is no unsupported region along the D-D axis, because of the arrangement of LF segments. In certain embodiments, the third slot 623 is provided to help with electrical isolation, e.g., to isolate lead 13 from lead 15. However, as will be appreciated, the specific location of the third slot 623 is not required to be in the middle. The third slot 623 also could be at an angle, as shown in FIG. 6D, discussed further herein. In addition, in some embodiments, the third slot 623 is not needed at all, as shown in FIGS. 6B and 6C, discussed further herein.

FIG. 7A is a cross-section view 700 of the first modified lead frame of FIG. 6A, with an exemplary first prior art semiconductor die 52 attached, as encapsulated with mold material 102, where the cross-section view 700 is taken along the C-C line of FIG. 6A, in accordance with one embodiment. The cross-section view 700 also shows lead pins 56, 58, 60, 62 visible, where these lead pins were not visible in FIG. 6A, because FIG. 6A shows the first modified lead frame 600 before encapsulation. These lead pins 56, 58, 60, 62 are also shown in the example embodiment of FIG. 17, discussed further below. As the cross-section view 700 shows, along the C-C line, the support for the die is coming from third LF segment 616 and second LF segment 614. By having the support coming from opposing corners, as FIGS. 6A and 7A show, that helps to increase a strength of the first modified lead frame along the center axis C-C. That is, in certain embodiments, the support coming from second LF segment 614 and third LF segment 616 together forms a type of diagonal support or bracing in the first modified lead frame 600, which helps to increase horizontal strength and stability (e.g., from forces acting in the horizontal direction, e.g., C-C direction, and from forces acting in the D-D direction), to further help to prevent die cracking along the C-C axis. In addition, as will be appreciated by those of skill in the art, a die would be easier to crack or break under 3-point bending. By providing the first slot 626 and second slot 630 at an angle (e.g., at a 45 degree angle, but this is not limiting), the arrangement is unlikely to form such a 3-point bend situation.

It will be understood that the embodiment of FIG. 6A alternately could be configured to be a “mirror” or “reverse” image of what is shown: i.e., to have the first LF segment 612 and fourth LF segment 618 be the ones with the projecting portions. If the embodiment of FIG. 6A were configured in that manner, there would still be a slot between the first LF segment 612 and third LF segment 616 along the D1-D1 axis, but the slot would be disposed mostly “above” the C-C axis. Similarly, there would still be a slot between the second LF segment 614 and the fourth LF segment 618 but the slot would be disposed mostly “below” the C-C axis.

Referring again to FIG. 6A, as will be understood, the first slot 626, second slot 630, and third slot 623 each provide a respective spacing that is configured to help prevent issues that might arise with magnetic field sensors or similar devices that may be located on a semiconductor die attached to the first modified lead frame 600 (e.g., as shown and discussed further below in FIGS. 8-10). These issues, such as current loops, may arise because of interaction with the conductive material of the first modified lead frame 600 with electric fields associated with the magnetic sensing element. These issues are understood in the art and are further explained in the aforementioned '025 patent, which describes how slots like the first slot 626, second slot 630 and/or third slot 623 can help to move a position of eddy currents that may arise due to a magnetic element in the semiconductor die and also can help to reduce a size (e.g., a diameter or path length) of the closed loops in which the eddy currents travel in the first modified lead frame 600 (“current loops”), to result in a smaller magnetic field error so that the magnetic element (e.g., a Hall effect element) experiences a smaller magnetic field from the eddy currents than it would otherwise experience, resulting in less error in the measured field and enhanced overall performance of the sensor.

Referring again to FIG. 6A, there is a first opening 620A that is formed between the first LF segment 612 and the second LF segment 614, wherein the first predetermined opening 620A has a corresponding first cutout width 621A and first cutout length 623A, all defined in between the first LF segment 612 and the second LF segment 614. Similarly, there is a second opening 620B that is formed between the third LF segment 616 and the fourth LF segment 618, wherein the second predetermined opening 620B has a corresponding second cutout width 621B and a second cutout depth 623B, as defined between the third LF segment 616 and the fourth LF segment 618. The first opening 620A and the second opening 620B are configured, sized, and arranged to ensure that the first modified lead frame 600 does not cover magnetic sensing components on a die that is attached to the first modified lead frame. The first opening 620A and second opening 620B also can be viewed to be slots. The first opening 620A has a first cutout length 623A and the entire length 623A of the first opening 620A corresponds to a supported slot region, as defined herein. Similarly, the second opening 620B has a length 623B and corresponds to a supported slot region, as defined herein.

The dimensions of each LF segment in the first modified lead frame 600 can be selected, based on the application, to ensure that the first opening 620A and the second opening 620B are each sized to accommodate a range of dies to be attached to the first modified lead frame 600, wherein the corresponding magnetic sensing elements on the range of dies, may be positioned in various locations on the die, but will be positioned so that the first modified lead frame 600 does not cover the magnetic sensing elements, while still providing sufficient support to the die. This is an improvement over the first prior art lead frame 10 of FIG. 1, which, although it had slots/openings to ensure it did not cover magnetic field sensors on a variety of dies, lacked sufficient support for the dies, leading to cracking. This also is an improvement over the second prior art lead frame 202 of FIG. 2, because the second prior art lead frame 202 of FIG. 2 had a slot 210 having a size that is usable with only certain prior art dies.

This can be seen in the example embodiments of FIGS. 8-10. FIG. 8 is a top view 800 of the first modified lead frame 600 of FIG. 6A, attached to the first type of semiconductor die 304 (first discussed in connection with FIG. 3), in accordance with one embodiment. As FIG. 8 illustrates, the first type of semiconductor die 304 is supported at each corner by first LF segment 612, second LF segment 614, third LF segment 616, and fourth LF segment 613, and the second opening 620B is configured so that it does not overlay the first magnetic field sensor 208.

FIG. 9 is a top view 900 of the first modified lead frame 600 of FIG. 6A, attached to the second type of semiconductor die 404 (first discussed in connection with FIG. 4), in accordance with one embodiment. As FIG. 9 illustrates, the second type of semiconductor die 404 is supported at each corner by first LF segment 612, second LF segment 614, third LF segment 616, and fourth LF segment 613. FIG. 9 illustrates that the second type of semiconductor die 404 does not lie equally on top of each LF segment, but that is not limiting. In FIG. 9, the position of the second type of semiconductor die 404 is configured to ensure that the second magnetic field sensor 408A and third magnetic field sensor 408B are disposed within first opening 620A and second opening 620B of the first modified lead frame 600.

FIG. 10 is a top view 1000 of the first modified lead frame 600 of FIG. 6A, attached to the third type of semiconductor die 504, in accordance with one embodiment. As FIG. 10 illustrates, the third type of semiconductor die 504 is supported at each corner by first LF segment 612, second LF segment 614, third LF segment 616, and fourth LF segment 613, where the third type of semiconductor die 504 is able to be approximately equally supported be each of these LF segments, because of the locations of the fourth magnetic field sensor 508A and fifth magnetic field sensor 508B. In FIG. 10, the position of the third type of semiconductor die 504 is configured to ensure that the fourth magnetic field sensor 508A and fifth magnetic field sensor 508B are disposed within first opening 620A and second opening 620B of the first modified lead frame 600.

FIGS. 8-10 show the first modified lead frame 600 with three different dies, which all have magnetic field sensors as part of the dies. As FIGS. 8-10 illustrate, the first opening 620A and the second opening 620B are configured so that the magnetic field sensors of each die “fit” within either or both of the first opening 620A and second opening 620B. Those of skill in the art will appreciate that the particular size(s) of one or both of first opening 620A and second opening 620B can be tailored to enable use with any particular one or more dies that have magnetic field sensors located thereon in various locations. For example, the width of either or both of the first cutout width 621A (FIG. 6A) and the second cutout width 621B (FIG. 6A) can vary based on the location and/or size of the one or more magnetic field sensors that are on a given die. In some embodiments, the first cutout width 621A may be smaller or larger than the second cutout width 621B, depending on locations of magnetic field sensors. Similarly, a first cutout length 623A and/or second cutout length 623B may vary (which may impact the size and shape of one or more of the LF segments), as will be appreciated, depending on the location(s) of the one or more magnetic field sensors that may be on a given die. Advantageously, the cutout widths and the cutout lengths/depths are configured so that the first opening 620A and/or the second opening 620B are sized to enable the first LF segment 612, second LF segment 614, third LF segment 616, and fourth LF segment 618, to have sizes and dimensions sufficient to support the die and help prevent cracking, to provide necessary electrical connections, and to provide sufficient room for any magnetic field sensor(s) on the dies.

The first modified lead frame 600 of FIGS. 6A and 8-10 is an embodiment that helps provide advantageous features including stronger mechanical support under the die to minimize and/or eliminate the risks of die cracking and built in features (e.g., the orientation and design of the LF segments, as well as the cutouts, slots, and/or openings provided) that help reduce magnetic reluctance, reduce eddy currents, and mitigate ESD, for optimum sensor performance.

In a further embodiment, the first modified lead frame 600 of FIG. 6A can be implemented without the third slot 622, as shown in FIG. 6B, which is a top view of a portion of a first alternate embodiment 680 of the first modified lead frame 600, in accordance with one embodiment and further as shown in FIG. 6C, which is a top view of a portion of a second alternate embodiment 681 of the first modified lead frame 600, in accordance with one embodiment. FIG. 6B is nearly identical to FIG. 6C, except that in FIG. 6B the second LF segment 614 is connected to lead 13 and in FIG. 6C, the second LF segment 614 is not connected to lead 13. FIG. 7B is a cross-section view 780 of the first alternate embodiment 680 of the first modified lead frame of FIG. 6B, as coupled to a die and encapsulated, taken along the C-C line of FIG. 6B, in accordance with one embodiment. FIG. 7C is a cross-section view 781 of the second alternate embodiment 681 of the first modified lead frame 600, taken along the C1-C1 line of FIG. 6C, in accordance with one embodiment.

Referring to FIGS. 6B-7C, the first alternate embodiment 680 and second alternate embodiment 681 are each similar to and possesses all the advantages of the first modified lead frame 600 as discussed above. However, the first alternate embodiment 680 and the second alternate embodiment 681 each includes only the first slot 626 and second slot 632, but not the third slot 623. Instead, in both FIG. 6B and FIG. 6C, an additional horizontal portion 627 of lead frame connects the second LF segment 614 to the third LF segment 616. FIG. 6C has the additional difference wherein the second LF segment 614 is not electrically connected to lead 13, to help ensure isolation between lead 15 and lead 13, if needed in a given application. Both the first alternate embodiment 680 and the second alternate embodiment 681 each can provide increased support and strength along the C-C axis, when used with magnetic field sensors that do not require as many slots to mitigate for current loops. As the cross-section views 780 and 781 illustrate, the support for the die, along the C-C axis (FIG. 6B) and C1-C1 axis (FIG. 6C), effectively looks like full support, while still providing most of the advantageous slots and cutouts of the first modified lead frame 600 of FIG. 6A.

The first alternate embodiment 680 of the first modified lead frame 600 and the second alternate embodiment 681 of the first modified lead frame 600 can be made of the same materials, having the same properties, thicknesses, planarity, etc., as discussed above in connection with the first modified lead frame 600, as will be appreciated. Depending on the needs of the application, one or more of the LF segments of a respective lead frame, may be made from electrically isolating material or electrically conductive material, or a combination thereof (e.g., an electrically isolated support material with one or more traces formed thereon made of electrically conductive material), as will be appreciated by those of skill in the art.

In yet another aspect embodiment, the first modified lead frame 600 of FIG. 6A can be implemented with the third slot 622 at an angle, as shown in FIG. 6D, which is a top view of a portion of a third alternate embodiment 690 of the first modified lead frame 600, in accordance with one embodiment. FIG. 7D is a cross-section view 790 of the third alternate embodiment 690 of FIG. 6D, in accordance with one embodiment. The third alternate embodiment 690 is similar to and possesses all the advantages of the first modified lead frame 600 as discussed above (e.g., can be made of the same types of materials, is substantially planar, etc.). However, the third slot 623 of FIG. 6A is instead implemented as a third angled slot 663, as shown in FIG. 6D. In addition, to implement the angled third slot, the second alternate embodiment 690 of the first modified lead frame 690 has certain LF segments that are slightly differently shaped than the corresponding LF segments in the first modified lead frame 600, to enable the formation of the third angled slot 663.

The first LF segment 612 of the second alternate embodiment is similar in shape to the first LF segment 612 of the first modified lead frame 600 of FIG. 6A. Similarly, the fourth LF segment 668 of the second alternate embodiment 690 is substantially similar in shape to the fourth LF segment 618 of the first modified lead frame 600 of FIG. 6A. However, as FIG. 6D shows, the second LF segment 664 of the second alternate embodiment 690 and the third LF segment 666 of the second alternate embodiment, differ in shape from the corresponding second LF segment 614 and third LF segment 616, of the first modified lead frame 600 of FIG. 6A.

The differences in shapes of the second LF segment 664 and third LF segment 666 help to form the third angled slot 663, which has a separation (spacing) 662, as shown in FIG. 6D. As will be appreciated by those of skill in the art, by providing the third angled slot 623 at an angle (e.g., at a 45 degree angle, but this is not limiting), the arrangement minimizes any areas that are unsupported along any axis along the shortest side of the die, meaning that the arrangement is unlikely to form a 3-point bend, which could lead to increased stress on a die and make the die vulnerable to cracking. Note that the arrangement shown in FIG. 6D also shows (via the dashed lines and outlines of possible locations of magnetic field sensors) how the various die designs with corresponding magnetic field sensors (e.g., as shown in FIGS. 8-10) would be able to work with the third alternative embodiment 690 of the first modified lead frame.

The second LF segment 664 of FIG. 6D has a first top projecting width 665A at one end of the third angled slot 663 and a second bottom projecting width 665B a second end of the third angled slot 663, which help to define the size and shape of the one side of the third angled slot 663. Similarly, the third LF segment 666 has a first top projecting width 667A at the first end of the other side of third angled slot 663 and a second bottom projecting width 667B at the second end of the other side of the third slot 663. As FIG. 6D shows, these widths, as well as the contours of the second LF segment 664 and third LF segment 666 are configured to have a mating shape along the third angled slot 663, wherein the mating shape is configured to maintain the consistency of the angled third slot spacing 662. The illustrated mating shape shown in FIG. 6D is not, of course, limiting, and may take various forms, as will be understood. Further, the third slot spacing 662 is shown to be identical in size along the length of the third angled slot 663, but this is not limiting. As one of skill in the art will appreciate, the third slot 662 could be tapered or otherwise have variations along its length, so long as some spacing or separation is maintained between the second LF segment 664 and the third LF segment 666.

The cross-section view 790 of FIG. 7D, which is taken along the G-G axis of FIG. 6D, is similar to that of FIG. 7A, and shows a cross-section view 790 of the second alternate embodiment of the first modified lead frame of FIG. 6A, with an exemplary first prior art semiconductor die 52 attached, as encapsulated with mold material 102, where the cross-section view 290 is taken along the G-G line of FIG. 6D, in accordance with one embodiment. The cross-section view 790 also shows lead pins 56, 58, 60, 62 visible, where these lead pins were not visible in FIG. 6D, because FIG. 6D shows the second alternate embodiment of the first modified lead frame 600 before encapsulation. As the cross-section view 790 shows, along the G-G line, the support for the die is coming from the third LF segment 666 and fourth LF segment 668. By having the support come from opposing corners, as FIGS. 6D and 7D show, that helps to increase a strength of the second alternate embodiment of the first modified lead frame along the center axis G-G. That is, similar to the embodiment of FIG. 6A, in certain embodiments, the support coming from second LF segment 664 and third LF segment 666 together forms a type of diagonal support or bracing in the second alternate embodiment 690 of the first modified lead frame 600, which helps to increase horizontal strength and stability (e.g., from forces acting in the horizontal direction, e.g., G-G direction, and from forces acting in the H-H direction), to further help to prevent die cracking along the G-G axis. In addition, as will be appreciated by those of skill in the art, a die would be easier to crack or break under 3-point bending. By providing the first slot 626, second slot 630, and third angled slot 663, all at respective angles (e.g., at a 45 degree angle, but this is not limiting), the arrangement is unlikely to form such a 3-point bend situation.

FIGS. 11-15, discussed further below, relate to an additional embodiment and lead frame design that also provides the above-listed advantageous features. FIG. 11 is a top view 1100 of a second modified lead frame 710, in accordance with one embodiment. The second modified lead frame 710 provides complete support in the horizontal direction (i.e., along F-F axis as shown in FIG. 11) for better robustness, while still having four LF segment portions (e.g., first LF segment portion 710A, second LF segment portion 710B, third LF segment portion 710C, and fourth LF segment portion 710D) for die support. The second modified lead frame 710 also includes a fifth LF segment portion 710E that overlays the geometric center 54 of the second modified lead frame 710 and which is interconnected to all the other LF segment portions of the second modified lead frame 710. The fifth LF segment portion 710E is configured to provide extra support in the horizontal direction along the F-F axis as well as in parallel with the F-F axis. In certain embodiments, the fifth LF segment portion 710E serves as a horizontal support portion of the second modified lead frame 710 and is disposed between the third cutout 718A and the fourth cutout 718b. The horizontal support portion is configured to provide support to a die (to be attached to the second modified lead frame 710) along a horizontal axis of the die. Advantageously, the fifth LF segment portion 710E is configured to support a majority of a horizontal axis of the die. Advantageously, the fifth LF segment portion 710E is configured to support a majority of a horizontal axis that runs through a center of the die. For brevity, the combination of the first LF segment portion 710A, the second LF segment portion 710B, the third LF segment portion 710C, the fourth LF segment portion 710D, and the fifth LF segment portion 701E, will be referred to herein as the set of second LF segment portions 711.

The first LF segment portion 710A and the second LF segment portion 710B are separated by a third cutout (opening) 718A that has a third cutout width 712A and a third cutout height 714A. The third LF segment portion 710C and the fourth LF segment portion 710D are separated by a fourth cutout (opening) 718B that has a fourth cutout width 712B and a fourth cutout height 714B. As will be understood, the dimensions and shape of the third cutout 718A and/or the fourth cutout 718B can vary based on the die(s) to be used with the second modified lead frame 710 (thus, effectively, the dimensions and shape of each LF segment portion 710A, 710B, 710C, and 710D likewise may vary in accordance with the application). The entire length of the third cutout height 714A of the third cutout 718A corresponds to a supported slot region, as defined herein. Similarly, the entire length of the fourth cutout height 714B of the fourth cutout 718B corresponds to a supported slot region, as defined herein. Each opening (e.g., third cutout 718A, fourth cutout 718B) creates a discontinuity between the first side of first surface 704 of the second modified lead frame 710 and the second opposing side of second surface 706 of the second modified lead frame 710.

The second modified lead frame 710, similar to the first modified lead frame 600, can be part of an array or strip of similar lead frames and thus has a first tie bar 32A, second tie bar 32B, third tie bar 32C, and fourth tie bar 32D, with the tie bars 32 serving a similar purpose for the second modified lead frame as they do for the first modified lead frame 600, so that discussion is not repeated here. The second modified lead frame 710, in certain embodiments, is substantially planar and has a first side 704 and a second opposing side 706, which is more fully shown in FIG. 12, discussed further herein. The second modified lead frame 710 can be made using similar materials and processes as discussed above in connection with the first prior art lead frame 10 and/or the first modified lead frame 600, as well as the materials and processes discussed in the patents that were incorporated by reference. The second modified lead frame 710 can have a similar thickness, as well. In addition, the second modified lead frame 710 can be operably connected to a die and manufactured into a package in ways similar to those described previously in connection with the first prior art lead frame 10 and/or the first modified lead frame 600.

As FIG. 11 illustrates, the second modified lead frame 710 is also configured to provide some support in the lengthwise direction (along the E-E axis of FIG. 11) while still providing the cutouts 718A, 718B, which are advantageously sized so as to be directly overlaying the one or more magnetic sensing element(s) of the die, where the cutouts 718A, 718B help to avoid the impact of eddy currents on the performance of a device made using the second modified lead frame 710, in a manner similar to that described previously for the first modified lead frame 600 of FIG. 6A. The second modified lead frame 710 includes a plurality of pin pad connections as well, such as first lead connection pad 21, second lead connection pad 22, third lead connection pad 23, fourth lead connection pad 24, fifth lead connection pad 25, sixth lead connection pad 26, seventh lead connection pad 27 and eighth lead connection pad 28.

The LF segment portions 710A, 710B, 710C, 710D of the second modified lead frame 710 differ from the LF segments 612, 614, 616, 618 of the first modified lead frame 600, in that the LF segment portions 710A, 710B, 710C, 710D are all interconnected and can be part of the same sheet of material, because they are not coupled to leads or lead pins that have to be electrically isolated. In contrast, the LF segments 612, 614, 616, 618 are separate and electrically isolated from each other, because they are interconnected to respective lead pins, as FIGS. 1A-1B show. In FIG. 11, each LF segment portion serves as a die attach portion, as will be appreciated.

FIG. 12 is a cross-section view 1200 of the second modified lead frame 710 of FIG. 11, as coupled to a die (in this example, the exemplary first prior art semiconductor die 52) and encapsulated in mold material 102, where the cross-section view 1200 is taken along the F-F line of FIG. 11, in accordance with one embodiment. As the cross-section view 1200 of FIG. 12 illustrates, along the F-F axis (horizontal direction), the second modified lead frame 710 provides full support under the exemplary first prior art semiconductor die 52. The second modified lead frame 710, as shown in FIG. 12, show approximate locations of first LF segment portion 710A, fifth LF segment portion 710E, and second LF segment portion 710B.

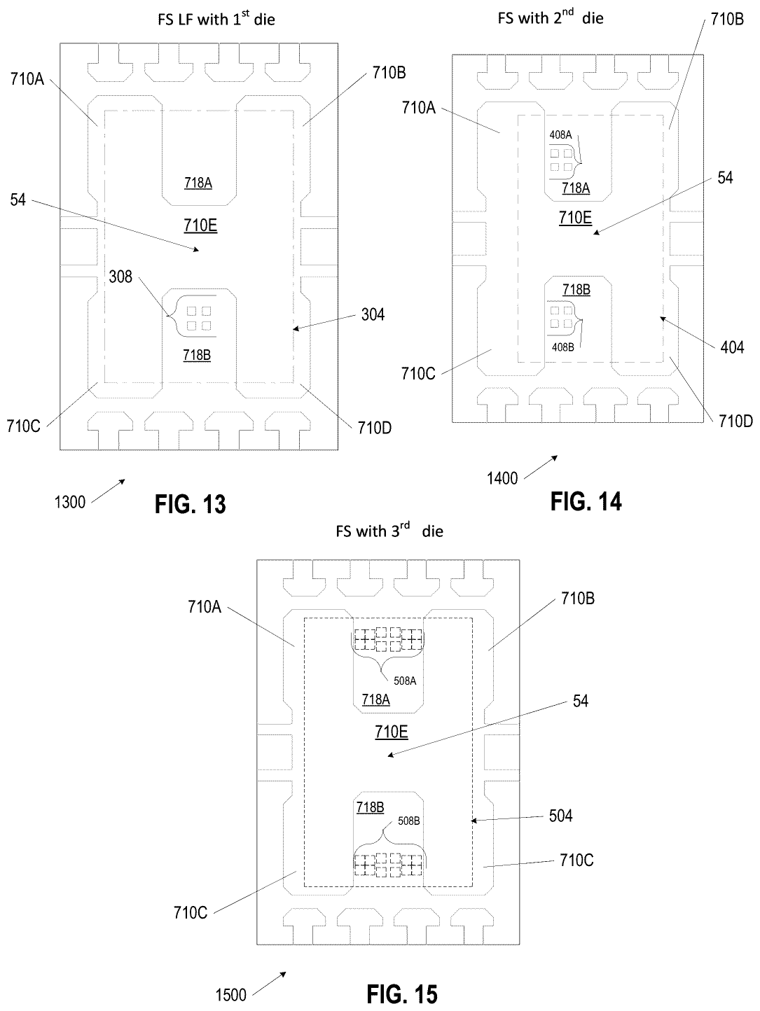

FIGS. 13-15 illustrate the second modified lead frame 710 with the same three different dies that were shown in FIGS. 8-10, where each of the dies have magnetic field sensors as part of the dies. As FIGS. 13-15 illustrate, the third cutout 718A and the fourth cutout 718B are configured so that the magnetic field sensors of each die “fit” within either or both of the third cutout 718A and the fourth cutout 718B. As noted previously, those of skill in the art will appreciate that the particular size(s) of one or both of third cutout 718A and fourth cutout 718B can be tailored to enable use with any particular one or more dies that have magnetic field sensors located thereon in various locations. For example, the third cutout width 712A and/or third cutout height 714A (for third cutout 718A) and/or the fourth cutout width 712B and fourth cutout height 714B (for fourth cutout 718B) can vary based on the location and/or size of the one or more magnetic field sensors that are on a given die. In some embodiments, the third cutout width 712A may be smaller or larger than the fourth cutout width 712B, depending on locations of magnetic field sensors. Similarly, a first cutout length 623A and/or second cutout length 623B may vary (which may impact the size and shape of one or more of the LF segments), as will be appreciated, depending on the location(s) of the one or more magnetic field sensors that may be on a given die. Advantageously, the cutout widths and the cutout depths are configured so that the third cutout 718A and/or the fourth cutout 718B are sized to enable the first LF segment portion 710A, second LF segment portion 710B, third LF segment portion 710C, and fourth LF segment portion 710D, as well as a fifth LF segment portion 710E (i.e., a center LF segment portion), to have sizes and dimensions sufficient to support the die and help prevent cracking, to provide necessary electrical connections, and to provide sufficient room for any magnetic field sensor(s) on the dies. Another advantage of the second modified lead frame 710 of FIG. 11, as compared to the prior art lead frame 202 of FIG. 2, is that the second modified lead frame 710 of FIG. 11 has all 8 of its leads unconnected, in comparison to the prior art lead frame 202 of FIG. 2, which has 4 of its 8 leads connected. Having more unconnected leads can be advantageous in certain applications and designs by providing more flexibility in electrical requirements, as will be appreciated.

FIG. 13 is a top view of the second modified lead frame 710 of FIG. 11, attached to the first type of semiconductor die 304, in accordance with one embodiment. As FIG. 13 illustrates, the first type of semiconductor die 304 is supported at each corner by first LF segment portion 710A, second LF segment portion 710B, third LF segment portion 710C, and fourth LF segment portion 710D, as well as in the middle (e.g., along the F-F axis of FIG. 11, not shown in FIG. 13) by fifth LF segment portion 710E. As FIG. 13 illustrates, the fourth cutout 718B is configured so that it does not overlay the first magnetic field sensor 208, and the position of the first type of semiconductor die 304 is configured so that its first magnetic field sensor 208 is aligned to lie within the fourth cutout 718B.

FIG. 14 is a top view 1400 of the second modified lead frame 710 of FIG. 11, attached to the second type of semiconductor die 404, in accordance with one embodiment. As FIG. 15 illustrates, the second type of semiconductor die 404 is supported at each corner by first LF segment portion 710A, second LF segment portion 710B, third LF segment portion 710C, and fourth LF segment portion 710D, as well as in the middle (e.g., along the F-F axis of FIG. 11, not shown in FIG. 14) by fifth LF segment portion 710E. FIG. 14 illustrates that the second type of semiconductor die 404 does not lie equally on top of each LF segment portion, but that is not limiting. In FIG. 14, the position of the second type of semiconductor die 404 is configured to ensure that the second magnetic field sensor 408A and third magnetic field sensor 408B are disposed within third cutout 718A and fourth cutout 718B, of the second modified lead frame 710.

FIG. 15 is a top view 1500 of the second modified lead frame 710 of FIG. 11, attached to the third type of semiconductor die 504, in accordance with one embodiment. As FIG. 15 illustrates, the third type of semiconductor die 504 is supported at each corner by first LF segment portion 710A, second LF segment portion 710B, third LF segment portion 710C, and fourth LF segment portion 710D, as well as in the middle (e.g., along the F-F axis of FIG. 11, not shown in FIG. 14) by fifth LF segment portion 710E. In FIG. 15, the third type of semiconductor die 504 is able to be approximately equally supported be each of these LF segments, because of the locations of the fourth magnetic field sensor 508A and fifth magnetic field sensor 508B. In FIG. 15, the position of the third type of semiconductor die 504 is configured to ensure that the fourth magnetic field sensor 508A and fifth magnetic field sensor 508B are disposed within third cutout 718A and fourth cutout 718B of the first modified lead frame.

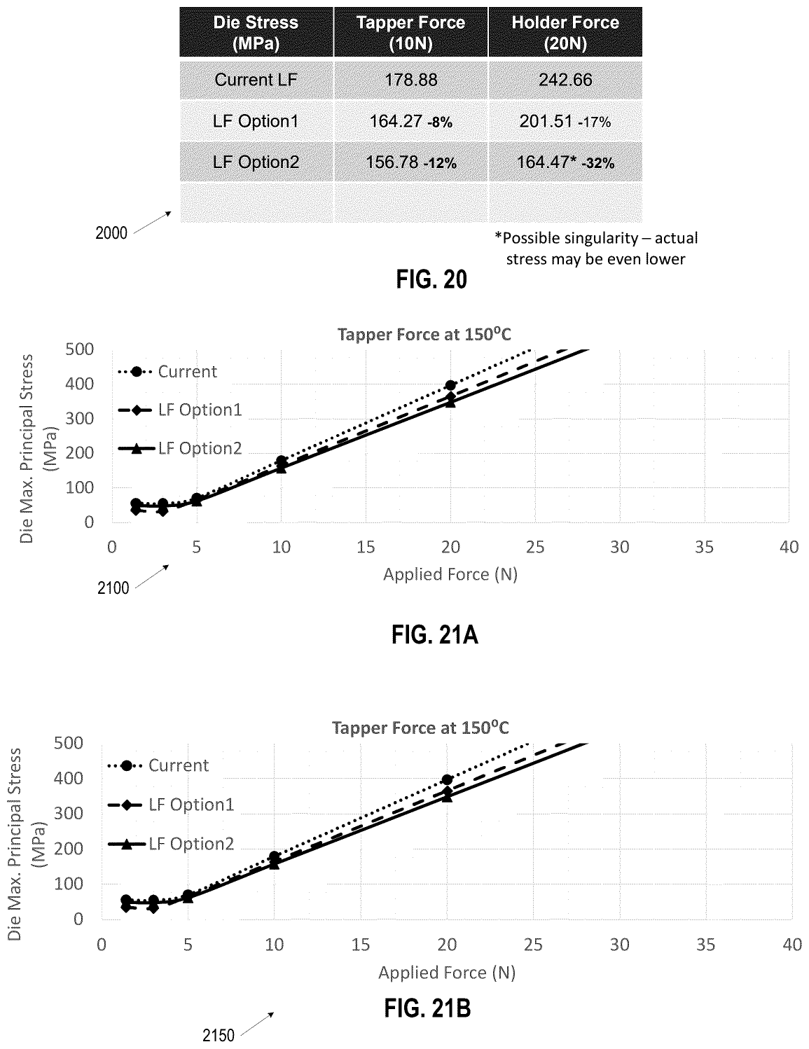

The modified lead frame embodiments of FIGS. 6A-10 and 11-15 have been configured into packages that have been tested and simulated in comparison to prior art packages using the first prior art lead frame 10 of FIG. 1A. FIG. 16 is top view 1600 of the exemplary prior art lead frame 10 of FIG. 1A as encapsulated into the first prior art type of the exemplary first prior art semiconductor die 52, o form a “current” package 1602, which was used during the simulation testing that generated the data shown in the graphs of FIGS. 20-23, in accordance with one embodiment. The current package 1602 of FIG. 16 is substantially similar to that of FIG. 1B. The current package 1602 of FIG. 16 corresponds to the “current” design data in the graphs of FIGS. 20-23, discussed further below.

FIG. 17 is a top view 1700 of the first modified lead frame 600 of FIG. 6A as encapsulated with the first prior art type of the exemplary first prior art semiconductor die 52, to form an “option 1” package 1702, which also was used during the simulation testing that generated the data shown in the graphs of FIGS. 20-23, in accordance with one embodiment. The top view 1700 shows that the option 1 package 1702 has similar pins to the current package 1602. The option 1 package 1702 of FIG. 17 corresponds to the “option 1” design data in the graphs of FIGS. 20-23 as discussed further below.

FIG. 18 is a top view 1800 of the second modified lead frame 710 of FIG. 11, as encapsulated with the first prior art type of the exemplary first prior art semiconductor die 52, to form an “option 2” package 1802, which was used during the simulation that generated the data shown in the graphs of FIGS. 20-23, in accordance with one embodiment. The option 2 package 1802 of FIG. 18 corresponds to the “option 2” design data in the graphs of FIGS. 20-23, as discussed further below.

Referring to FIGS. 16-18, for each simulation, certain features of each package were made to be identical, so that the lead frame features could be compared. For example, the simulation assumed that the die was made from anisotropic silicon material and that each lead frame was made of EFTEC 64T material (which, as noted previously, is a copper substrate material made from copper, zinc, tin, and chromium and plated with silver). It was assumed that each die and lead frame were overmolded with EME-E670C epoxy molding compound, available from Sumimoto Bakelite Co., Ltd., of Tokyo, Japan. In each of FIGS. 16-18, it is assumed that the die attach is done using LOCTITE ABLESTIK 8006NS material, which is a non-conductive die attach material available from HENKEL LOCTITE of Rocky Hill, CT., USA.

FIGS. 19A and 19 B are graphics showing simulated test conditions during tapper and holder force simulation testing. In the simulation testing of both FIG. 19A and FIG. 19B, the boundary conditions included a reference temperature of 175 degrees Celsius and thermal loads of 150 degrees Celsius. FIG. 19A is a first graphic 1900 depicting the locations of applied tapper force for the simulation testing associated with the graphs of FIGS. 20-23, in accordance with one embodiment. As FIG. 19A shows, for each package, the tapper force was applied at the location pointed to by arrow 1902, which lies along the G-G axis (i.e., an axis in parallel with the shortest side of the package being tested, which as noted previously was the area where die cracking was occurring). In addition, tapper force was applied to the external package surface at the locations 1904, 1906, 1908, and 1910, as shown in FIG. 19A. The sets of pins shown with diagonal shading, e.g., set 1912 and 1914, were assumed to have frictionless support when tapper force was applied.

FIG. 19B is a second graphic 1950 depicting the locations of applied holder force for the simulation testing associated with the graphs of FIGS. 20-23, in accordance with one embodiment. As FIG. 19B shows, for each package, the holder force was applied both at a designated location along the G-G axis (e.g., location 1952) as well as at the locations 1956, 1954, and 1956 in the cross section view. The areas of frictionless support in FIG. 19B include the locations labeled 1956 and 1958, which are the supporting areas. Similar to the concept of 3-point bending, the frictionless support locations 1956 and 1958 are two beams that enable a package to be seated, where the holder applies the force in the region 1952 as shown.

FIG. 20 is a chart 2000 of simulation results for die stress under holder force, comparing the prior art lead frame of FIG. 1 to the first modified lead frame 600 of FIG. 6A and the second modified lead frame 710 of FIG. 11, as encapsulated into the structures shown in FIGS. 16-18, respectively, in accordance with one embodiment. The data in the chart 2000 is extracted from the graphs of FIG. 21A and FIG. 21B, further discussed below. As the chart 2000 shows, the “option 1” design (FIG. 17), which corresponded to the first modified lead frame 600 and the “option 2” design (FIG. 18), which corresponded to the second modified lead frame 710, each reduced die stress under both tapper force and holder force.

For the tapper force simulation test data, the tapper force was applied from the bottom of the device, so the lead frame can't support the die under loads but is used to help distribute the applied force more evenly to reduce stress on the die. Both option 1 (first modified lead frame 600) and option 2 (second modified lead frame 710) reduced stress on the die as compared to the current lead frame (first prior art lead frame 10). With an applied force of 10 Newtons (N), the current design (first prior art lead frame 10) experienced stress of 178.88 MegaPascals (MPa). In contrast, with the same applied force, the option 1 (first modified lead frame 600) experienced 164.27 MPa, an 8% reduction, and the option 2 (second modified lead frame 710) experienced 156.78 MPa, a 12% reduction.

Regarding holder force, under a holder force of 20 N, the prior art lead frame 10 of FIG. 1, corresponding to the simulated package of FIG. 16, had a resultant stress of 242.66 MPa, but the option 1 lead frame (first modified lead frame 600) experienced a stress of 201.51 MPa, a 17% reduction in stress. The option 2 lead frame (second modified lead frame 710) performed even better, having a resultant stress of 164.47 MPa, a 32% reduction in stress as compared to the prior art lead frame 10 (current design). In addition, the simulation chart notes that there is a possible singularity associated with the data for the option 2 lead frame stress, so the actual stress may be even lower, with a better improvement over the prior art lead frame.

FIG. 21A is a graph 2100 of simulation testing results, showing die max principal stress as a function of applied tapper force, for the prior art lead frame of FIG. 1, the first modified lead frame of FIG. 6A and the second modified lead frame of FIG. 11, encapsulated into the structures shown in FIGS. 16-18, respectively, in accordance with one embodiment. FIG. 21B is a graph of simulation results, showing die max principal stress as a function of applied holder force, for the prior art lead frame of FIG. 1, the first modified lead frame of FIG. 6A, and the second modified lead frame of FIG. 11, encapsulated into the structures shown in FIGS. 16-18, respectively, in accordance with one embodiment. As FIG. 21A illustrates, for Tapper force, the improvement in reduction of die stress is consistent beginning at applied forces of about 5 N or more, with option 2 (second modified lead frame 710) showing consistently more improvement, but with both the option 1 (first modified lead frame 600) and option 2 (second modified lead frame 710) having improved performance as compared to the current (first prior art lead frame 10). As FIG. 21B illustrates, for Holder force, the improvement in reduction of dies stress also is consistent beginning at applied forces of about 5 N or more, with option 2 (second modified lead frame 710) having nearly double the improvement vs option 1 (first modified lead frame 600) as applied force increases, but with both the first modified lead frame 600 and second modified lead frame 710 showing measurable and significant improvement over the current lead frame (first prior art lead frame 10).

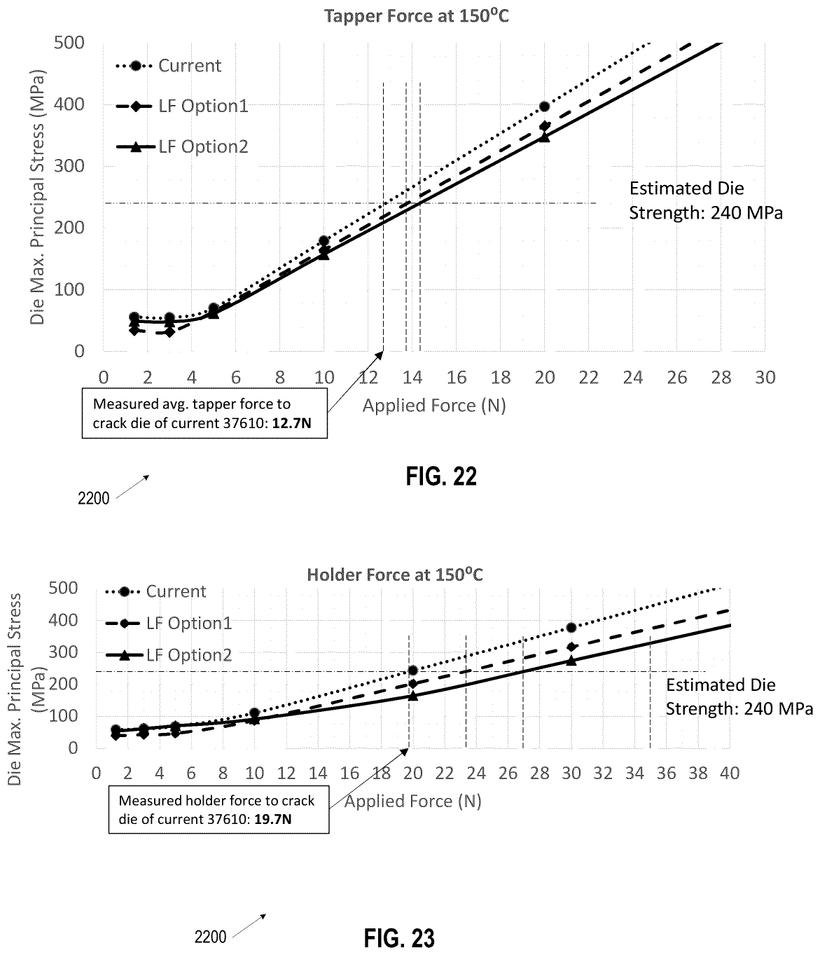

FIG. 22 is a graph 2200 of a graph of simulation testing results, showing die max principal stress as a function of applied tapper force, for the prior art lead frame of FIG. 1, the first modified lead frame of FIG. 6A, and the second modified lead frame of FIG. 11, encapsulated into the structures shown in FIGS. 16-18, respectively. FIG. 22 shows simulated tapper force to crack die for each type of lead frame, in accordance with one embodiment. As FIG. 22 illustrates the simulated tapper force to crack the die using the current lead frame (first prior art lead frame 10 of FIG. 1), which is found at the junction of the die strength line and each curve, is approximately 12.7N. In contrast, the simulated tapper force to crack the die using the option 1 lead frame (first modified lead frame 600), at the same estimated die strength of 240 MPa, is approximately 13.8N, and the simulated tapper force to crack the die using the option 2 lead frame (second modified lead frame 710) is approximately 14.4N.

FIG. 23 is a graph 2300 of simulation testing results, showing die max principal stress as a function of applied holder force, for the prior art lead frame of FIG. 1, the first modified lead frame of FIG. 6A, and the second modified lead frame of FIG. 11, encapsulated into the structures shown in FIGS. 16-18, respectively. FIG. 23 shows simulated holder force to crack die for each type of lead frame, in accordance with one embodiment. As FIG. 23 illustrates the simulated holder force to crack the die using the current lead frame (first prior art lead frame 10 of FIG. 1), which is found at the junction of the die strength line and each curve, is approximately 19.7N. In contrast, the simulated holder force to crack the die using the option 1 lead frame (first modified lead frame 600), at the same estimated die strength of 240 MPa, is approximately 23.4 N, and the simulated holder force to crack the die using the option 2 lead frame (second modified lead frame 710) is approximately 27N.

Based on the simulation testing of FIGS. 20-23, using the option 1 lead frame (first modified lead frame 600) requires approximately 8% more force to crack the die and using the option 2 lead frame (second modified lead frame 710) requires approximately 13% more force to crack the die. Thus, both embodiments of the modified lead frame are expected to improve the resistance of a semiconductor die to cracking and to reduce the die cracking issue discussed above.

The exemplary embodiments discussed above, which optimize and improve resistance to die cracking, especially in a horizontal direction (which in these examples corresponds to the direction parallel to the shortest side of the package), are useful and adaptable for many different types of circuits and packages that include dies that are coupled to lead frames, especially dies that include magnetic sensing component such as Hall effect sensors. The embodiments discussed herein also can be adapted to work with technology such as System-in-Package (SiP) technology in a variety of applications, such as automotive applications. Other embodiments of the may include applications for use in pressure sensors, and other contactless sensor packages in general in which it is desirable to have integrated components that may need to be configures so as to be not blocked by a lead frame structure, such as magnetic field sensors.

While exemplary embodiments contained herein discuss the use of magnetic field sensor such as a Hall effect sensor, the disclosure is not so limited. It would be apparent to one of ordinary skill in the art that other types of magnetic field sensors may also be used in place of or in combination with a Hall element. For example, the embodiments herein can be implemented with devices such as anisotropic magnetoresistance (AMR) sensor and/or a Giant Magnetoresistance (GMR) sensor. In the case of GMR sensors, the GMR element is intended to cover the range of sensors comprised of multiple material stacks, for example: linear spin valves, a tunneling magnetoresistance (TMR), or a colossal magnetoresistance (CMR) sensor. In other embodiments, the sensor includes a back bias magnet. The dies can be formed independently from Silicon, GaAs, InGaAs, InGaAsP, SiGe or other suitable material, as will be appreciated.

In addition, it will be appreciated by those of ordinary skill in the art that the package types, shapes, and dimensions, can be readily varied to suit a particular application both in terms of the electrical and magnetic requirements as well as any packaging considerations. It will also be appreciated that the various features shown and described herein in connection with the various embodiments can be selectively combined. For example, the any of the slots in the first modified lead frame 600 of FIG. 6A could be adapted into or combined with the second modified lead frame 710 of FIG. 11 (e.g., by just incorporating the third slot 623 in the middle of fifth LF segment portion 710E).

For purposes of illustrating the present embodiments, the disclosed embodiments are described as embodied in a specific configuration and using special logical arrangements, but one skilled in the art will appreciate that the device is not limited to the specific configuration but rather only by the claims included with this specification. In addition, it is expected that during the life of a patent maturing from this application, many relevant technologies will be developed, and the scopes of the corresponding terms are intended to include all such new technologies a priori.

In this disclosure, the terms “comprises,” “comprising”, “includes”, “including”, “having” and their conjugates at least mean “including but not limited to”. As used herein, the singular form “a,” “an” and “the” includes plural references unless the context clearly dictates otherwise. Various elements, which are described in the context of a single embodiment, may also be provided separately or in any suitable subcombination. It will be further understood that various changes in the details, materials, and arrangements of the parts that have been described and illustrated herein may be made by those skilled in the art without departing from the scope of the following claims.

Throughout the present disclosure, absent a clear indication to the contrary from the context, it should be understood individual elements as described may be singular or plural in number. For example, the terms “circuit” and “circuitry” and “module” may include either a single component or a plurality of components, which are either active and/or passive and are connected or otherwise coupled together to provide the described function. Within the drawings, like or related elements have like or related alpha, numeric or alphanumeric designators. Further, while the disclosed embodiments have been discussed in the context of implementations using discrete components, including some components that include one or more integrated circuit chips), the functions of any component or circuit may alternatively be implemented using one or more appropriately programmed processors, depending upon the signal frequencies or data rates to be processed and/or the functions being accomplished. Similarly, in addition, in the Figures of this application, the total number of elements or components shown is not intended to be limiting; those skilled in the art can recognize that the number of a particular component or type of element can, in some instances, be selected to accommodate the particular user needs.

In describing and illustrating the embodiments herein, in the text and in the figures, specific terminology (e.g., language, phrases, product brands names, etc.) may be used for the sake of clarity. These names are provided by way of example only and are not limiting. The embodiments described herein are not limited to the specific terminology so selected, and each specific term at least includes all grammatical, literal, scientific, technical, and functional equivalents, as well as anything else that operates in a similar manner to accomplish a similar purpose. Furthermore, in the illustrations, Figures, and text, specific names may be given to specific features, elements, circuits, modules, tables, software modules, systems, etc. Such terminology used herein, however, is for the purpose of description and not limitation.

Although the embodiments included herein have been described and pictured in an advantageous form with a certain degree of particularity, it is understood that the present disclosure has been made only by way of example, and that numerous changes in the details of construction and combination and arrangement of parts may be made without departing from the spirit and scope of the described embodiments. Having described and illustrated at least some the principles of the technology with reference to specific implementations, it will be recognized that the technology and embodiments described herein can be implemented in many other, different, forms, and in many different environments. The technology and embodiments disclosed herein can be used in combination with other technologies. In addition, all publications and references cited herein are expressly incorporated herein by reference in their entirety. Individual elements of different embodiments described herein may be combined to form other embodiments not specifically set forth above. Various elements, which are described in the context of a single embodiment, may also be provided separately or in any suitable sub-combination. It should also be appreciated that other embodiments not specifically described herein are also within the scope of the following claims.

What is claimed is:

1. A magnetic field sensor, comprising:
a die;
a first magnetic field sensing element supported by the die, the first magnetic field sensing element disposed at a first position on the die;
a second magnetic field sensing element supported by the die, the second magnetic field sensing element disposed at a second position on the die, wherein the second position is spaced apart from the first position;
a lead frame configured for supporting the die, the lead frame having opposed first and second surfaces and comprising:
at least one die attach segment to which the die is attached, the at least one die attach segment configured to support the die;
a first opening formed in the die attach segment, the first opening configured to create a first discontinuity between the first and second surfaces of the lead frame, wherein a size and a location of the first discontinuity is selected so that that there is no lead frame covering the first magnetic field sensing element; and
a second opening formed in the die attach segment, the second opening configured to create a second discontinuity between the first and second surfaces of the lead frame, wherein a size and a location of the second discontinuity is selected so there is no lead frame covering the second magnetic field sensing element, wherein the second opening is spaced apart from the first opening; and
wherein the die attach segment is configured to include at least one horizontal support portion disposed between the first opening and the second opening, wherein the horizontal support portion has a size that is configured to provide support to the die along a predetermined portion of at least one predetermined horizontal axis of the die.

2. The magnetic field sensor of claim 1, wherein the predetermined portion of the at least one predetermined horizontal axis of the die comprises a majority of the at least one predetermined horizontal axis of the die.

3. The magnetic field sensor of claim 1, wherein the predetermined portion of the at least one predetermined horizontal axis of the die, comprises an entirety of the at least one predetermined horizontal axis of the die.

4. The magnetic field sensor of claim 1, wherein that least one predetermined horizontal axis runs through a center of the die.

5. The magnetic field sensor of claim 1, wherein the first opening has a first opening length and a first opening width and wherein the size of the horizontal support portion is based on at least one of the first opening width and the first opening length.

6. The magnetic field sensor of claim 1, wherein the at least one predetermined horizontal axis comprises a horizontal axis aligned with a center of the die.

7. The magnetic field sensor of claim 1, wherein the first opening is symmetrical about a vertical axis running through a center of the die.

8. The magnetic field sensor of claim 1, further comprising a plurality of leads configured for operable connection to the die, wherein the lead frame is electrically isolated from at least some of the plurality of leads.

9. A magnetic field sensor, comprising:
a die
a first magnetic field sensing element supported by the die, the first magnetic field sensing element disposed at a first position on the die;
a lead frame configured for supporting the die, the lead frame having opposing first and second surfaces and comprising:
a first die attach segment to which the die is attached;
a second die attach segment to which the die is attached, the second die attach segment comprising a first portion, a second portion, and a third portion, wherein:
the first portion is spaced apart from the first die attach segment via a first opening;
the second portion is aligned along a horizontal axis of the die and is configured to support the die along a predetermined portion of the horizontal axis of the die; and
a third portion is spaced apart from the first die attach segment via a first slot; and
a third die attach segment to which the die is attached, the third die attach segment spaced apart from the third portion of the second die attach segment via a second opening and spaced apart from the second portion of the second die attach segment via a second slot;
wherein at least one of the first opening and the second opening is configured to create a respective discontinuity between the first and second surfaces of the lead frame, wherein a size and a location of the respective discontinuity is selected so that there is no lead frame covering the magnetic field sensing element; and
wherein at least one of the first slot and the second slot is configured to mitigate a current loop arising from operation of the magnetic field sensing element.

10. The magnetic field sensor of claim 9 wherein the horizontal axis of the die runs through a center point of the die.

11. The magnetic field sensor of claim 9, wherein the first die attach segment and the first portion of the second die attach segment are disposed on opposing sides of a vertical axis that runs through a center of the die.

12. The magnetic field sensor of claim 9, wherein the third portion of the second die attach segment and the third die attach segment are disposed on opposing sides of a vertical axis that runs through a center of the die.

13. The magnetic field sensor of claim 9, wherein at least one of the first slot and second slot is at an angle with respect to the horizontal axis of the die.

14. The magnetic field sensor of claim 13 wherein at least one of the first slot and second slot is at an angle with respect to the horizontal axis of the die.

15. The magnetic field sensor of claim 9, further comprising a third slot disposed within the second portion and aligned along a vertical axis of the die.

16. The magnetic field sensor of claim 15, wherein the third slot is aligned along a vertical axis that runs through a center point of the die.

17. The magnetic field sensor of claim 15, wherein the third slot is configured to be at an angle to a vertical axis that runs through a center point of the die.

18. The magnetic field sensor of claim 9, further comprising a plurality of leads configured for operable connection to the die.

19. The magnetic field sensor of claim 18, wherein the first die attach segment, second die attach segment, and third die attach segment are each configured to be in operable communication with a respective lead from the plurality of leads.

20. The magnetic field sensor of claim 19, wherein the first die attach segment, second die attach segment, and third die attach segment are configured to be electrically isolated from each other.
